(19) United States
(12) Patent Application Publication
(10) Pub. No.: US 2012/0109548 A1
(43) Pub. Date: May 3, 2012

(54) MEASUREMENT APPARATUS, MEASUREMENT METHOD AND RECORDING MEDIUM

(75) Inventor: Koji ASAMI, Saitama (JP)

(73) Assignee: ADVANTEST CORPORATION, Tokyo (JP)

(21) Appl. No.: 13/273,234

(22) Filed: Oct. 14, 2011

(30) Foreign Application Priority Data
Oct. 27, 2010 (JP) 2010-241054

(51) Int. Cl. G01R 31/00; G06F 19/00

(52) U.S. Cl. 702/58

(57) ABSTRACT

A measurement apparatus for measuring a characteristic (for example, EVM) of a device under measurement provided with a quadrature modulator or a quadrature demodulator is provided. The measurement apparatus includes an I-Q error measuring section that measures a frequency characteristic of an I-Q error of the device under measurement, and an error amount calculating section that calculates, based on the frequency characteristic of the I-Q error, an error amount observed when the device under measurement is supplied with a predetermined signal.

### CROSS REFERENCE TO RELATED APPLICATION

The contents of the following Japanese patent application are incorporated herein by reference:
No. 2010-241054 filed on Oct. 27, 2010.

### BACKGROUND

1. Technical Field

The present invention relates to a measurement apparatus, a measurement method and a recording medium.

2. Related Art

Digital communication devices are evaluated, for example, by their error vector magnitudes (EVMs). The manufacturers of digital communication devices measure the EVMs of the digital communication devices, judge whether the measured EVMs are acceptable and adjust the EVMs, for example, prior to shipment.

To ship digital communication devices compatible with a plurality of communication standards, manufacturers are disadvantageously required to measure the EVMs for each communication standard. In addition, some communication standards supply the digital communication devices with long signals, which result in lengthy measurement processes.

### SUMMARY

To solve the above-described problems, a first aspect of the innovations may include a measurement apparatus for measuring a characteristic of a device under measurement provided with a quadrature modulator or a quadrature demodulator. The measurement apparatus includes an I-Q error measuring section that measures a frequency characteristic of an I-Q error of the device under measurement; and an error amount calculating section that calculates, based on the frequency characteristic of the I-Q error, an error amount observed when the device under measurement is supplied with a predetermined signal. A measurement method and a recording medium are also provided.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates the configuration of a measurement apparatus 10 relating to an embodiment of the present invention, together with a device under measurement 200.

FIG. 2 illustrates the model of a quadrature modulator with an I-Q error.

FIG. 3 illustrates the model of a quadrature demodulator with an I-Q error.

FIG. 4 illustrates, as an example, an ideal signal that is expected to be output from the device under measurement 200, a measured signal that is actually output from the device under measurement 200, and an error vector indicative of the error that is measured on the I-Q plane between the ideal signal and the measured signal.

FIG. 5 illustrates the configuration of an error amount calculating section 30 when the device under measurement 200 is configured to modulate or demodulate an OFDM signal.

FIG. 6 illustrates the component at an angular frequency ω₀ of the ideal signal, which is calculated by an ideal signal calculating section 32.

FIG. 7 illustrates the component at the angular frequency ω₀ of the predicted signal, which is calculated by a predicted signal calculating section 34.

FIG. 8 illustrates the configuration of the error amount calculating section 30 when the device under measurement 200 is configured to modulate or demodulate an SC-FDMA signal.

FIG. 9 illustrates, as an example, the filter characteristic (H_{I}(ω)) of the I-signal path of the device under measurement 200.

FIG. 10 illustrates, as an example, the filter characteristic (H_{Q}(ω)) of the Q-signal path of the device under measurement 200.

FIG. 11 illustrates the configuration of an I-Q error measuring section 20 relating to the embodiment, together with a quadrature modulator 300.

FIG. 12 illustrates, as an example, a multitone signal that is output from an ideal quadrature modulator in response to a reference I signal and a reference Q signal that are simultaneously supplied to the ideal quadrature modulator.

FIG. 13 illustrates, as an example, when to supply the reference I signal and the reference Q signal, when the reference I and Q signals are supplied at different timings to the quadrature modulator 300.

FIG. 14 illustrates the model of the error of the quadrature modulator 300.

FIG. 15 illustrates, as an example, the frequency characteristic of the I-Q error.

FIG. 16 is a flow chart illustrating an exemplary flow of operations performed by a calculating section 122 relating to the embodiment.

FIG. 17 illustrates the configuration of a modification example of the I-Q error measuring section 20, together with a quadrature demodulator 400.

FIG. 18 illustrates an exemplary hardware configuration of a computer 1900 relating to an embodiment of the present invention.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

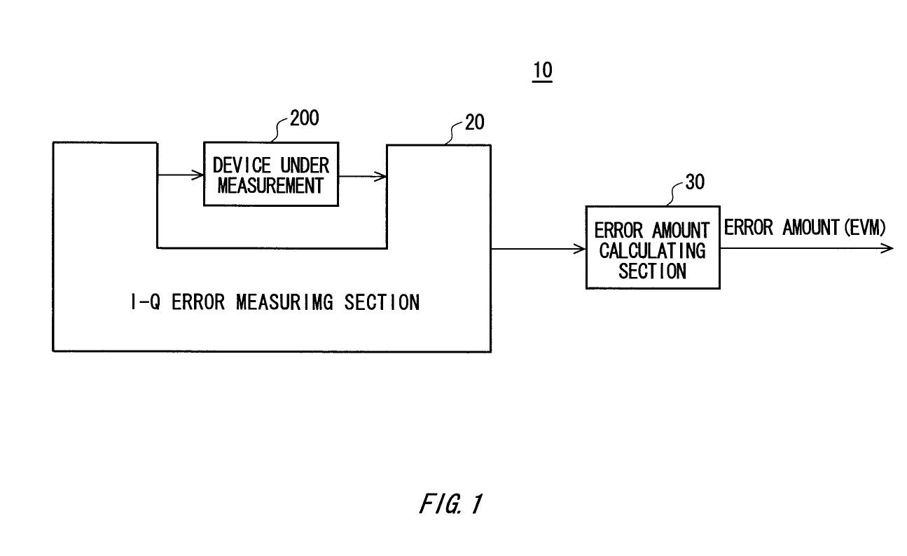

FIG. 1 illustrates the configuration of a measurement apparatus 10 relating to an embodiment of the present invention, together with a device under measurement 200. The measurement apparatus 10 measures the characteristics of the device under measurement 200 that includes a quadrature modulator or a quadrature demodulator. In the present embodiment, the measurement apparatus 10 measures the error vector magnitude (EVM) of the device under measurement 200.

The measurement apparatus 10 includes an I-Q error measuring section 20 and an error amount calculating section 30. The I-Q error measuring section 20 measures the frequency characteristic of the I-Q error of the device under measurement 200.

Here, the frequency characteristic of the I-Q error of the device under measurement 200 can be given by the following equation.

H(ω)=(H_{Q}(ω)/H_{I}(ω))·e^{jθ}

Here, H(ω) denotes the frequency characteristic of the I-Q error of the device under measurement 200, H_{I}(ω) denotes the filter characteristic of the I-signal path of the device under measurement 200, H_{Q}(ω) denotes the filter characteristic of the Q-signal path of the device under measurement 200, and θ denotes the carrier phase error.

In other words, the frequency characteristic of the I-Q error of the device under measurement 200 can be represented as the result of phase-shifting, by an amount corresponding to the carrier phase error, the ratio of the filter characteristic of the Q-signal path of the device under measurement 200 to the filter characteristic of the I-signal path of the device under measurement 200.

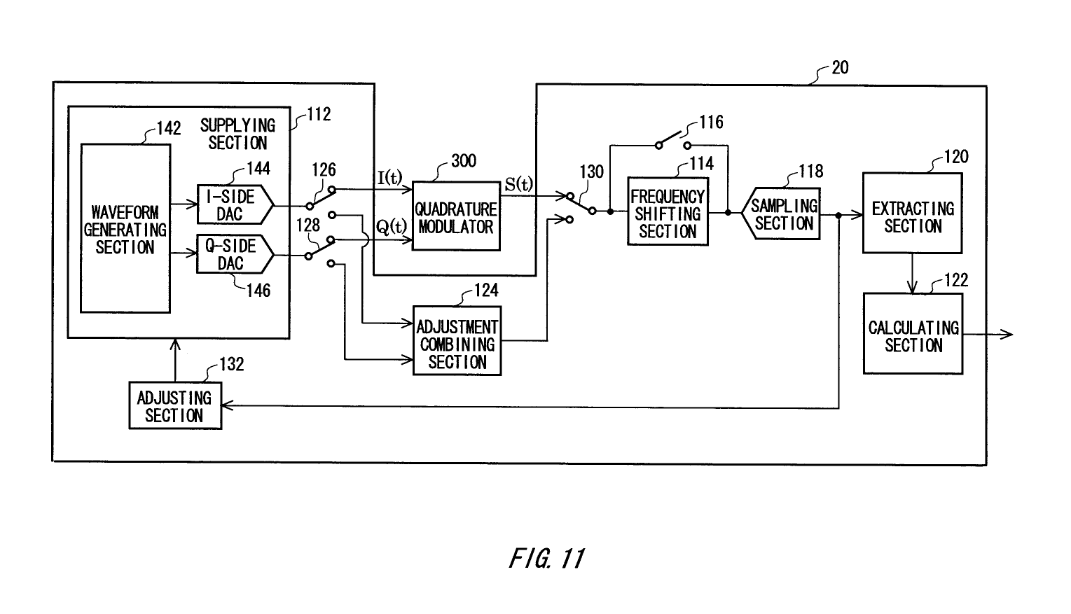

Thus, the I-Q error measuring section 20 relating to the embodiment separately measures the filter characteristic of the I-signal path H_{I}(ω) and the filter characteristic of the Q-signal path H_{Q}(ω), which together form the frequency characteristic of the I-Q error. The I-Q error measuring section 20 also measures the phase error between the carrier signals separately supplied to the I- and Q-signal paths of the device under measurement 200 (i.e., the carrier phase error θ). The I-Q error measuring section 20 will be described in more detail with reference to FIG. 11 and subsequent drawings.

The error amount calculating section 30 calculates an error amount observed when a predetermined signal is supplied to the device under measurement 200, based on the frequency characteristic of the I-Q error of the device under measurement 200, which is measured by the I-Q error measuring section 20. In the present embodiment, the error amount calculating section 30 calculates the EVM of the device under measurement 200.

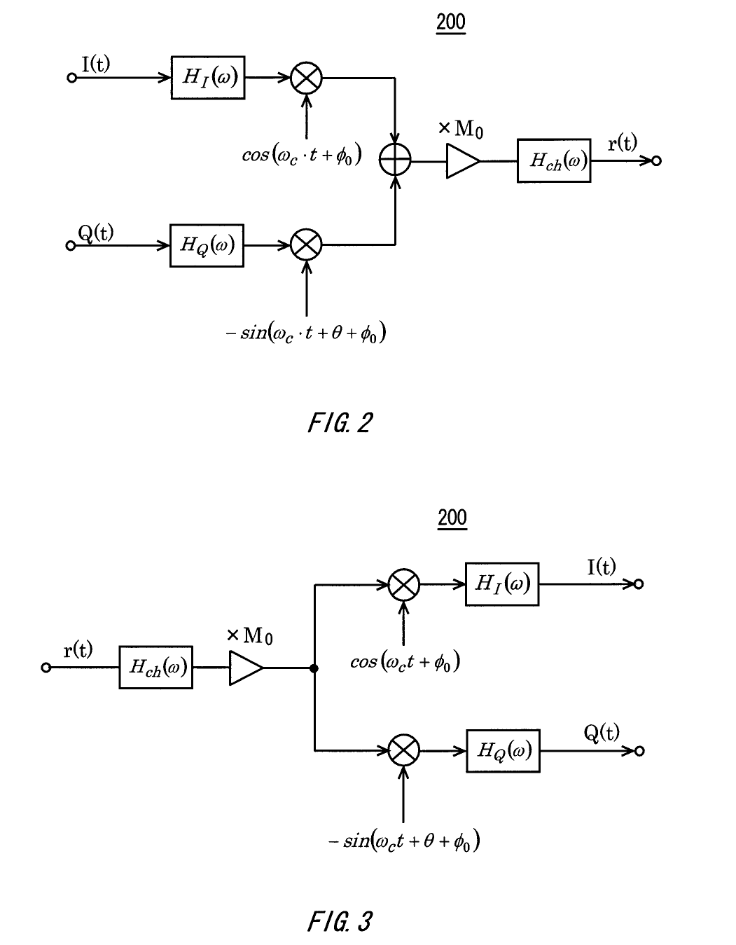

FIG. 2 illustrates the model of a quadrature modulator with an I-Q error. FIG. 3 illustrates the model of a quadrature demodulator with an I-Q error.

As shown in FIG. 2, a quadrature modulator with an I-Q error is represented by a model including the filter characteristic of an I-signal path H_{I}(ω) and the filter characteristic of a Q-signal path H_{Q}(ω). According to the model of the quadrature modulator with an I-Q error, the filter characteristic of the I-signal path H_{I}(ω) is inserted between the input end of the I component of a baseband signal (I(t)) and an I-side multiplier. According to the model of the quadrature modulator with an I-Q error, the filter characteristic of the Q-signal path H_{Q}(ω) is inserted between the input end of the Q component of the baseband signal (Q(t)) and a Q-side multiplier.

A quadrature modulator including a channel characteristic is represented by a model including a channel characteristic Hch(ω). In the model of the quadrature modulator including the channel characteristic, the channel characteristic Hch(ω) is inserted between an amplifier that amplifies a modulated signal (r(t)) and the output end of the modulated signal (r(t)).

As shown in FIG. 3, the quadrature demodulator with an I-Q error is represented by a model including the filter characteristic of an I-signal path H_{I}(ω) and the filter characteristic of a Q-signal path H_{Q}(ω). According to the model of the quadrature demodulator with an I-Q error, the filter characteristic of the I-signal path H_{I}(ω) is inserted between an I-side multiplier and the output end of the I component of a baseband signal (I(t)). According to the model of the quadrature demodulator with an I-Q error, the filter characteristic of the Q-signal path H_{Q}(ω) is inserted between a Q-side multiplier and the output end of the Q component of the baseband signal (Q(t)).

A quadrature demodulator including a channel characteristic is represented by a model including a channel characteristic Hch(ω). In the model of the quadrature demodulator including the channel characteristic, the channel characteristic Hch(ω) is inserted between the input end of a modulated signal (r(t)) and an amplifier that amplifies the modulated signal (r(t)).

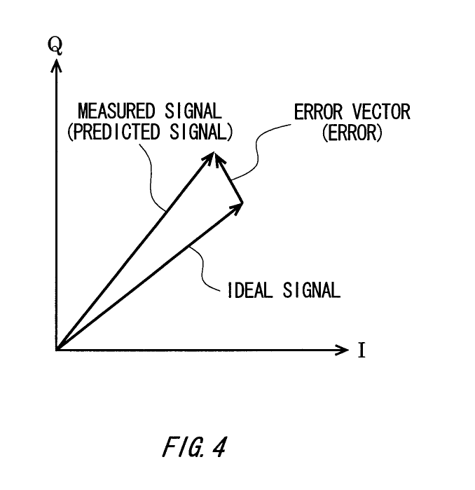

FIG. 4 illustrates, as an example, an ideal signal that is expected to be output from the device under measurement 200, a measured signal that is actually output from the device under measurement 200, and an error vector indicative of the error that is measured on the I-Q plane between the ideal signal and the measured signal. A case is assumed where a baseband signal of a predetermined signal point is modulated by a quadrature modulator and the modulated signal is demodulated by an ideal quadrature demodulator. In this case, the baseband signal resulting from the demodulation has an error with respect to an ideal signal (i.e., the baseband signal input into the quadrature modulator). This error is attributable to the quadrature modulator and represented as an error vector on the I-Q plane.

Another case is assumed where a baseband signal of a predetermined signal point is modulated by an ideal quadrature modulator and the modulated signal is demodulated by a quadrature demodulator. In this case, the baseband signal resulting from the demodulation has an error with respect to an ideal signal (i.e., the baseband signal input into the ideal quadrature modulator). This error is attributable to the quadrature demodulator and represented as an error vector on the I-Q plane.

Here, the EVM for the quadrature modulator and the quadrature demodulator is represented as the root mean square (RMS) of the error vectors calculated for a plurality of signal points. The EVM indicates the performance of the quadrature modulator and the quadrature demodulator. For example, a general EVM measuring apparatus supplies a device under measurement with a baseband signal of a plurality of predetermined signal points (for example, a baseband signal defined by a communication standard) and measures the signal points of the signal that is resultantly output from the device under measurement. The EVM measuring apparatus calculates the root mean square of the error vectors of the measured signal points and outputs the result as the EVM.

Here, the error amount calculating section 30 relating to the present embodiment calculates a value equivalent to the above-described EVM, based on the frequency characteristic of the I-Q error measured by the I-Q error measuring section 20. More specifically, the error amount calculating section 30 calculates an ideal signal that is expected to be output from an I-Q-error-free model of the device under measurement 200 in response to a predetermined signal (for example, a signal defined by a communication standard) input thereto. The error amount calculating section 30 also calculates a predicted signal that is expected to be output from an I-Q-error-inclusive model of the device under measurement 200, which includes the I-Q error measured by the I-Q error measuring section 20, in response to a predetermined signal (for example, a signal defined by a communication standard) input thereto. The error amount calculating section 30 calculates the EVM based on the error between the ideal signal and the predicted signal.

Having the above-described error amount calculating section 30, the measurement apparatus 10 can calculate the EVM without the need of actually supplying the device under measurement 200 with a predetermined signal (for example, a signal defined by a communication standard) and measuring the output signal resultantly output therefrom. Accordingly, the measurement apparatus 10 can easily measure the EVM within a short period of time.

The error amount calculating section 30 may calculate the EVM using, as the predetermined signal, a signal of a signal point with the highest signal strength. Specifically speaking, the error amount calculating section 30 may calculate the EVM based on the error between an ideal signal and a predicted signal that are expected to be output from the models of the device under measurement 200 in response to a signal of a signal point with the highest signal strength input thereto. In this manner, the error amount calculating section 30 can measure a worst possible value for the EVM of the device under measurement 200.

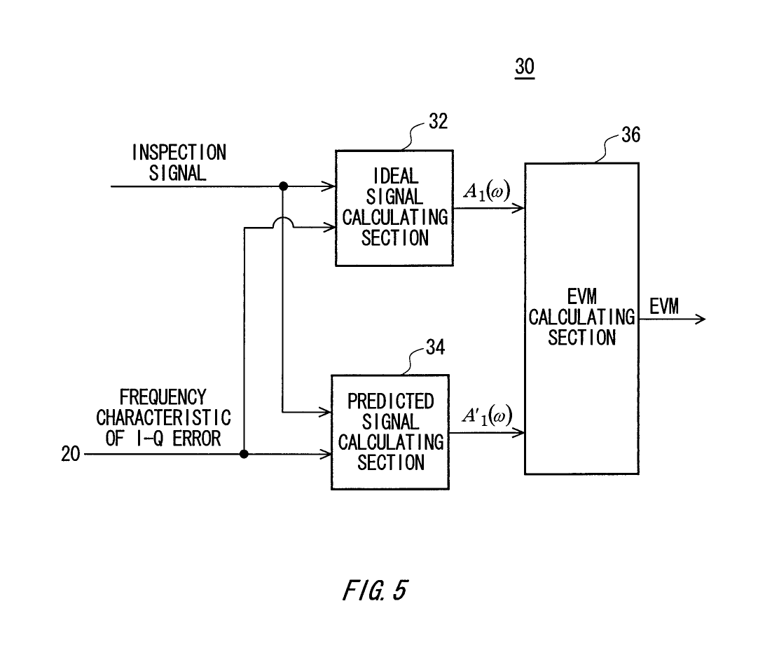

FIG. 5 illustrates the configuration of the error amount calculating section 30 when the device under measurement 200 is configured to modulate or demodulate an orthogonal frequency division multiplexing (OFDM) signal. When the device under measurement 200 is configured to modulate or demodulate an OFDM signal, the error amount calculating section 30 includes an ideal signal calculating section 32, a predicted signal calculating section 34, and an EVM calculating section 36.

The ideal signal calculating section 32 calculates an ideal signal that is expected to be output from an I-Q-error-free model of the device under measurement 200 in response to a predetermined signal input thereto. For example, the ideal signal calculating section 32 calculates an ideal signal that is expected to be output from an I-Q-error-free ideal model of the device under measurement 200 in response to an inspection signal input thereto. Here, the inspection signal is designed to calculate the EVM and defined by a OFDM-based communication standard (for example, IEEE 802.11a).

The predicted signal calculating section 34 calculates a predicted signal that is expected to be output from an I-Q-error-inclusive model of the device under measurement 200, which includes the I-Q error measured by the I-Q error measuring section 20, in response to a predetermined signal input thereto. For example, the predicted signal calculating section 34 calculates a predicted signal that is expected to be output from an I-Q-error-inclusive model of the device under measurement 200, which includes the I-Q error measured by the I-Q error measuring section 20, in response to the same signal as the inspection signal input into the ideal signal calculating section 32 input thereto.

The EVM calculating section 36 calculates, for a single symbol of the OFDM signal, the error (distance) on the I-Q plane between the ideal signal and the predicted signal in association with each of a plurality of frequencies (a plurality of subcarriers). Furthermore, the EVM calculating section 36 calculates, for the single symbol, the root mean square of the errors (distances) on the I-Q plane associated with the frequencies (subcarriers). The EVM calculating section 36 outputs the root mean square calculated for the single symbol as the EVM. Alternatively, the EVM calculating section 36 may output, as the EVM, an average among the root mean squares calculated for a plurality of symbols of the OFDM signal.

In the above-described manner, the error amount calculating section 30 can calculate the EVM without the need of actually inputting an inspection signal compatible with the OFDM standard into the device under measurement 200 and measuring the resulting output signal. As a result, the measurement apparatus 10 can easily and swiftly perform the EVM calculation when the device under measurement 200 is configured to modulate or demodulate an OFDM signal.

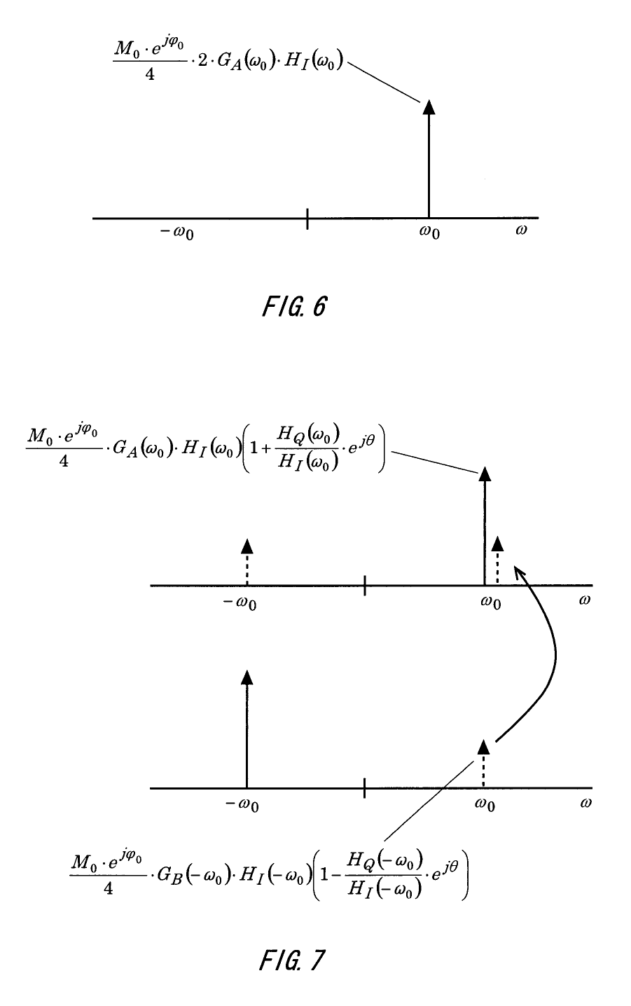

FIG. 6 illustrates the component at an angular frequency (ω₀) of the ideal signal calculated by the ideal signal calculating section 32. The ideal signal is not affected by the I-Q error of the device under measurement 200. Thus, the component at a given angular frequency ω0 of the ideal signal (A(ω₀)) does not affect the DC-symmetric mirror angular frequency (−ω₀) and is not affected by the component at the mirror angular frequency (−ω₀) either. Thus, the component at the angular frequency ω0 of the ideal signal (A(ω₀)) is represented by the following Expression 111.

$${A}_{1} ( {ω}_{0} ) = \frac{{M}_{0} \cdot {e}^{{jϕ}_{0}}}{4} \cdot 2 \cdot {G}_{A} ( {ω}_{0} ) \cdot {H}_{1} ( {ω}_{0} ) \qquad ( 111 )$$

Here, ω₀ denotes the angular frequency, M₀ denotes the gain of the modulated signal for the model of the device under measurement 200, φ₀ denotes the initial phase of the carrier signal for the model of the device under measurement 200, G_{A}(ω₀) denotes the signal component at the angular frequency ω₀ of the predetermined signal (the inspection signal) input into the model of the device under measurement 200, and H_{I}(ω₀) denotes the component of the angular frequency ω₀ of the filter characteristic of the I-signal path, where the frequency characteristic of the I-Q error of the device under measurement 200 is separated into the filter characteristic of the I-signal path and the filter characteristic of the Q-signal path. These definitions apply to Expressions 111 to 124.

The ideal signal calculating section 32 uses the above Expression 111 to calculate the component at the angular frequency ω₀ of the ideal signal (A(ω₀)). The ideal signal calculating section 32 uses Expression 111 to calculate the component for each of a plurality of angular frequencies (subcarriers) and outputs the calculated components as the ideal signal.

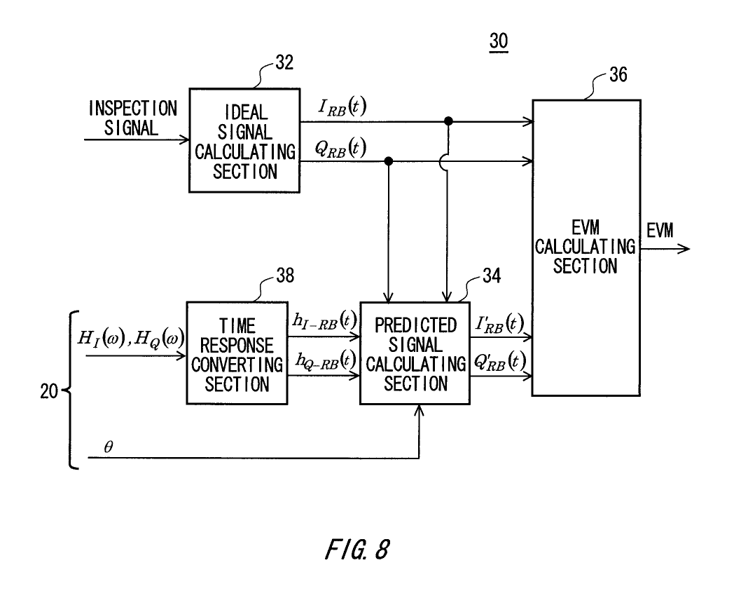

FIG. 7 illustrates the component at an angular frequency ω₀ of the predicted signal calculated by the predicted signal calculating section 34. The predicted signal is affected by the I-Q error of the device under measurement 200. Thus, the component at a given angular frequency ω₀ of the predicted signal (A′(ω₀)) affects the DC-symmetric mirror angular frequency (−ω₀) and is affected by the component of the mirror angular frequency (−ω₀). Accordingly, the component at the angular frequency ω₀ of the predicted signal (A′(ω₀)) is equivalent to the sum of (i) the component (the positive component) corresponding to the signal component (G_{A}(ω₀)) at the angular frequency ω₀ of the predetermined signal (the inspection signal) and (ii) the component (the negative component) corresponding to the signal component (G_{B}(−ω₀)) at the DC-symmetric mirror angular frequency (−ω₀) of the predetermined signal (the inspection signal).

The component at the angular frequency ω₀, included in the positive component, is given by the following Expression 112.

$$\frac{{M}_{0} \cdot {e}^{{jϕ}_{0}}}{4} \cdot {G}_{A} ( {ω}_{0} ) \cdot {H}_{I} ( {ω}_{0} ) ( 1 + \frac{{H}_{Q} ( {ω}_{0} )}{{H}_{I} ( {ω}_{0} )} \cdot {e}^{jθ} ) \qquad ( 112 )$$

Here, H_{Q}(ω₀) denotes the component at the angular frequency ω₀ of the filter characteristic of the Q-signal path, where the frequency characteristic of the I-Q error of the device under measurement 200 is separated into the filter characteristic of the I-signal path and the filter characteristic of the Q-signal path, and θ denotes the I-Q carrier phase error of the device under measurement 200. These definitions apply to Expressions 111 to 124.

In other words, the component of the angular frequency ω₀, which corresponds to the positive component, is obtained by adding together (i) the value obtained by multiplying together the signal component G_{A}(ω₀) at the angular frequency ω₀ of the predetermined signal (the inspection signal) and the component H_{I}(ω₀) at the angular frequency ω₀ of the filter characteristic of the I-signal path and (ii) the value obtained by multiplying together the signal component G_{A}(ω₀) at the frequency ω₀ of the inspection signal, the component H_{Q}(ω₀) at the angular frequency ω₀ of the filter characteristic of the Q-signal path, and the phase of the carrier phase error e^{jθ}, and then by multiplying the result of the addition with the value corresponding to the gain of the modulated signal (M₀/4) and the initial phase e^{jφ0} of the carrier signal.

The component at the angular frequency −ω₀, included in the negative component, is given by the following Expression 113.

$$\frac{{M}_{0} \cdot {e}^{{jϕ}_{0}}}{4} \cdot {G}_{B} ( - {ω}_{0} ) \cdot {H}_{I}^{*} ( {ω}_{0} ) ( 1 - \frac{{H}_{Q}^{*} ( {ω}_{0} )}{{H}_{I}^{*} ( {ω}_{0} )} \cdot {e}^{jθ} ) \qquad ( 113 )$$

Here, G_{B}(−ω₀) denotes the signal component at the angular frequency −ω₀ of the predetermined signal (the inspection signal) input into the model of the device under measurement 200, H_{I}*(ω₀) denotes the complex conjugate of the component at the angular frequency ω₀ of the filter characteristic of the I-signal path of the device under measurement 200, and H_{Q}*(ω₀) denotes the complex conjugate of the component at the angular frequency ω₀ of the filter characteristic of the Q-signal path of the device under measurement 200. These definitions apply to Expressions 111 to 124.

In other words, the component at the angular frequency ω₀, which corresponds to the negative component, is obtained by adding together (i) the value obtained by multiplying together the signal component G_{B}(−ω₀) at the angular frequency −ω₀ of the predetermined signal (the inspection signal) and the complex conjugate H_{I}*(ω₀) of the component at the angular frequency ω₀ of the filter characteristic of the I-signal path and (ii) the value obtained by multiplying together the signal component G_{B}(−ω₀) at the frequency −ω₀ of the inspection signal, the complex conjugate H_{Q}*(ω₀) of the component at the angular frequency ω₀ of the filter characteristic of the Q-signal path, and the phase e^{jθ} of the carrier phase error, and then by multiplying the result of the addition with the value corresponding to the gain of the modulated signal (M₀/4) and the initial phase e^{jφ0} of the carrier signal.

The component A′(ω₀) at the angular frequency ω₀ of the predicted signal is the signal obtained by adding together the positive component represented by Expression 112 and the negative component represented by Expression 113. The component A′(ω₀) of the angular frequency ω₀ of the predicted signal is given by the following Expression 114.

$${A}_{1}^{′} ( {ω}_{0} ) = \frac{{M}_{0} \cdot {e}^{{jϕ}_{0}}}{4} \{ {G}_{A} ( {ω}_{0} ) \cdot {H}_{1} ( {ω}_{0} ) ( 1 + \frac{{H}_{Q} ( {ω}_{0} )}{{H}_{1} ( {ω}_{0} )} \cdot {e}^{jθ} ) + {G}_{B} ( - {ω}_{0} ) \cdot {H}_{I}^{*} ( {ω}_{0} ) ( 1 - \frac{{H}_{Q}^{*} ( {ω}_{0} )}{{H}_{I}^{*} ( {ω}_{0} )} \cdot {e}^{jθ} ) \} \qquad ( 114 )$$

The predicted signal calculating section 34 uses Expression 114 to calculate the predicted signal. Specifically speaking, the predicted signal calculating section 34 calculates, for each of a plurality of frequencies, the predicted signal corresponding to the result of adding together (i) the component obtained by multiplying together the signal component G_{A}(ω₀) at the frequency of the predetermined signal and the component H(ω) at the frequency of the frequency characteristic of the I-Q error and (ii) the component obtained by multiplying together the signal component G_{B}(ω₀) at the mirror frequency of the frequency of the predetermined signal and the complex conjugate H*(ω) of the component at the frequency of the frequency characteristic of the I-Q error.

The EVM calculating section 36 uses the ideal signal calculated from the equation 111 and the predicted signal calculated from the equation 114 to calculate a value corresponding to the root mean square of the distances (errors) that are measured on the I-Q plane between the ideal signal and the predicted signal for a plurality of frequencies (subcarriers) and outputs the resulting value as the EVM. In the above-described manner, the error amount calculating section 30 can calculate the EVM of the device under measurement 200.

In the present embodiment, the error amount calculating section 30 collectively performs the calculations of the ideal signal calculating section 32, the predicted signal calculating section 34, and the EVM calculating section 36. In this case, the error amount calculating section 30 calculates the EVM using the following Expression 115.

$$E V M = {C}_{1} \cdot \sqrt{{\sum }_{k = 1}^{ToneNum} \frac{{\vert \frac{{M}_{0} \cdot {e}^{{jϕ}_{0}}}{4} \{ \begin{matrix}\begin{matrix}{G}_{A} ( {ω}_{k} ) ( {H}_{I} ( {ω}_{k} ) + {H}_{Q} ( {ω}_{k} ) \cdot {e}^{jθ} ) + \\ {G}_{B} ( - {ω}_{k} ) ( \begin{matrix}{H}_{I}^{*} ( {ω}_{k} ) - \\ {H}_{Q}^{*} ( {ω}_{k} ) \cdot {e}^{jθ}\end{matrix} ) -\end{matrix} \\ 2 {G}_{A} ( {ω}_{k} ) \cdot {H}_{I} ( {ω}_{k} )\end{matrix} \} \vert}^{2}}{ToneNum \cdot {\vert \frac{{M}_{0} \cdot {e}^{{jϕ}_{0}}}{4} \vert}^{2}}} = {C}_{1} \cdot \sqrt{\frac{{\sum }_{k = 1}^{ToneNum} {\vert \{ \begin{matrix}{G}_{A} ( {ω}_{k} ) ( {H}_{I} ( {ω}_{k} ) + {H}_{Q} ( {ω}_{k} ) \cdot {e}^{jθ} ) + \\ \begin{matrix}{G}_{B} ( - {ω}_{k} ) ( {H}_{I}^{*} ( {ω}_{k} ) - {H}_{Q}^{*} ( {ω}_{k} ) \cdot {e}^{jθ} ) - \\ 2 {G}_{A} ( {ω}_{k} ) \cdot {H}_{I} ( {ω}_{k} )\end{matrix}\end{matrix} \} \vert}^{2}}{ToneNum}} = {C}_{1} \cdot \sqrt{{\sum }_{k = 1}^{ToneNum} \frac{{\vert \{ \begin{matrix}{G}_{A} ( {ω}_{k} ) ( - {H}_{I} ( {ω}_{k} ) + {H}_{Q} ( {ω}_{k} ) \cdot {e}^{jθ} ) + \\ {G}_{B} ( - {ω}_{k} ) ( \begin{matrix}{H}_{I}^{*} ( {ω}_{k} ) - \\ {H}_{Q}^{*} ( {ω}_{k} ) \cdot {e}^{jθ}\end{matrix} )\end{matrix} \} \vert}^{2}}{ToneNum}} \qquad ( 115 )$$

Here, ToneNum denotes the number of subcarriers contained in the OFDM signal, k denotes the subcarrier number to identify one of the subcarriers contained in the OFDM signal, ωₖ denotes the angular frequency of the subcarrier k, G_{A}(ωₖ) denotes the signal component at the subcarrier k of the predetermined signal input into the model of the device under measurement 200, G_{B}(−ωₖ) denotes the signal component at the mirror subcarrier −k of the subcarrier k of the predetermined signal input into the model of the device under measurement 200, H_{I}(ωₖ) denotes the component at the angular frequency ωₖ of the filter characteristic of the I-signal path and H_{Q}(ωₖ) denotes the component at the angular frequency ωₖ of the filter characteristic of the Q-signal path, where the frequency characteristic of the I-Q error is separated into the filter characteristic of the I-signal path and the filter characteristic of the Q-signal path, H_{I}*(ωₖ) denotes the complex conjugate of the component at the angular frequency ωₖ of the filter characteristic of the I-signal path, H_{Q}*(ωₖ) denotes the complex conjugate of the component at the angular frequency ω^{k} of the filter characteristic of the Q-signal path, and C₁ denotes the constant determined according to the standard of the OFDM signal. These definitions apply to Expressions 111 to 124.

The error amount calculating section 30 may calculate the root mean square given by Expression 115 for each of the plurality of symbols of the OFDM signal, calculate the average among the obtained root mean squares, and output the average as the EVM. In this manner, the error amount calculating section 30 can calculate the EVM of the device under measurement 200 when the inspection signal input into the device under measurement 200 has a plurality of symbols.

When calculating the EVM using Expression 115, the error amount calculating section 30 may assign, to the variables G_{A}(ωₖ) and G_{B}(−ωₖ), the average of the signal components of a plurality of symbols, where the average is calculated for each subcarrier. In this manner, the error amount calculating section 30 can also calculate the EVM of the device under measurement 200 when the inspection signal input into the device under measurement 200 has a plurality of symbols.

As discussed above, the measurement apparatus 10 relating to the present embodiment can easily perform the EVM calculation when the device under measurement 200 is configured to modulate or demodulate OFDM signals.

An OFDM signal communication system corrects its channel characteristic by transmitting a modulated signal containing a pilot signal of a predetermined signal point, such as a long training sequence (LTS). This type of OFDM signal communication standard may require that the EVM be measured after the channel characteristic has been corrected using the pilot signal.

To measure the EVM of a device compatible with such an OFDM standard, the error amount calculating section 30 uses the following Expression 116.

$$E V M = {C}_{1} \cdot \sqrt{\frac{{\sum }_{k = 1}^{ToneNum} {\vert \{ \begin{matrix}{G}_{A} ( {ω}_{k} ) ( - {H}_{I} ( {ω}_{k} ) + {H}_{Q} ( {ω}_{k} ) \cdot {e}^{jθ} ) \cdot {C}_{P} ( {ω}_{k} ) + \\ {G}_{B} ( - {ω}_{k} ) ( {H}_{I}^{*} ( {ω}_{k} ) - {H}_{Q}^{*} ( {ω}_{k} ) \cdot {e}^{jθ} ) \cdot {C}_{P} ( - {ω}_{k} )\end{matrix} \} \vert}^{2}}{ToneNum}} \qquad ( 116 )$$

Here, C_{P}(ωₖ) denotes the component at the angular frequency (ωₖ) of the correction characteristic for correcting the channel characteristic, and C_{P}(−ωₖ) denotes the component at the angular frequency (−ωₖ) of the correction characteristic for correcting the channel characteristic.

Specifically speaking, when calculating the EVM, the error amount calculating section 30 multiplies the signal component G_{A}(ωₖ) at the subcarrier k with the component C_{P}(ωₖ) at the subcarrier k of the correction characteristic for correcting the channel characteristic by transmitting a modulated signal containing a pilot signal and multiplies the signal component G_{B}(−ωₖ) at the mirror subcarrier with the component C_{P}(−ωₖ) at the mirror subcarrier −k of the correction characteristic. In this manner, the error amount calculating section 30 can calculate the EVM of a device in compliance with a standard that requires the EVM measurement to be performed after the channel characteristic of the device has been corrected using a pilot signal.

For example, wireless LAN standards such as IEEE 802.11 require that EVM measurement be performed after channel characteristic correction has been carried out using a pilot signal. According to such standards, there are subcarriers containing a pilot signal for representing the channel characteristic of the I channel only and subcarriers containing a pilot signal for representing the channel characteristic of the Q channel only.

Accordingly, when the device under measurement 200 is compatible with wireless LAN standards such as IEEE 802.11, the error amount calculating section 30 assumes that the component C_{P}(ωₖ) at the subcarrier k of the correction characteristic for correcting the channel characteristic of the I channel only is 1 and the component C_{P}(−ωₖ) of the mirror subcarrier −k of the correction characteristic for correcting the channel characteristics of the I channel only is 1. Furthermore, the error amount calculating section 30 assumes that the component C_{P}(ωₖ) at the subcarrier k of the correction characteristic for correcting the channel characteristic of the Q channel only is (−1/Hc(ω)) and the component C_{P}(−ωₖ) at the mirror subcarrier k of the correction characteristic for correcting the channel characteristic of the Q channel only is (1/Hc(ω)).

Here, Hc(ω) denotes an estimated transmission path characteristic. By performing the above-described correction, the error amount calculating section 30 can calculate the EVM of a device compatible with wireless LAN standards such as IEEE 802.11.

As another example, there are standards based on the orthogonal frequency division multiplexing access (OFDMA) scheme, such as IEEE 802.16. According to such standards, the I and Q channel characteristics of every one of the subcarriers are corrected.

Accordingly, when the device under measurement 200 is compatible with OFDMA-based standards such as IEEE 802.16, the error amount calculating section 30 assumes that the component C_{P}(ωₖ) at the subcarrier k of the correction characteristic for every subcarrier is (−1/(j+Hc(ω))) and the component C_{P}(−ωₖ) at the mirror subcarrier −k is (1/(j+Hc(ω))). By performing the above-described correction, the error amount calculating section 30 can calculate the EVM of a device compatible with the OFDMA-based standard such as IEEE 802.16.

FIG. 8 illustrates the configuration of the error amount calculating section 30 when the device under measurement 200 is configured to modulate or demodulate a single-carrier frequency division multiple access (SC-FDMA) signal. When the device under measurement 200 is configured to modulate or demodulate an SC-FDMA signal, the error amount calculating section 30 includes the ideal signal calculating section 32, the EVM calculating section 36, a time response converting section 38, and the predicted signal calculating section 34.

The ideal signal calculating section 32 calculates the I component and the Q components of the ideal signal represented in the time domain, for each of a plurality of resource blocks corresponding to a plurality of frequency multiplexing ranges defined in the SC-FDMA signal. For example, the ideal signal calculating section 32 calculates the I and Q components of the ideal signal, represented in the time domain, that is expected to be output from an I-Q-error-free ideal model of the device under measurement 200 in response to an inspection signal input thereto. The inspection signal is designed to calculate the EVM of a device compatible with a SC-FDMA-based communication standard (for example, Super 3G (LTE)). Furthermore, the ideal signal calculating section 32 may calculate the I and Q components of the ideal signal represented in the time domain for a plurality of subsymbols.

The time response converting section 38 calculates, for each of the resource blocks, the impulse response of the filter characteristic of the I-signal path and the impulse response of the filter characteristic of the Q-signal path, where the frequency characteristic of the I-Q error is separated into the filter characteristic of the I-signal path and the filter characteristic of the Q-signal path.

The predicted signal calculating section 34 calculates, for each of the resource blocks, the I component of the predicted signal, represented in the time domain, that is obtained by convolving the I component of the ideal signal in the time domain and the impulse response of the filter characteristic of the I-signal path. Furthermore, the predicted signal calculating section 34 calculates, for each of the resource blocks, the Q component of the predicted signal, represented in the time domain, that is obtained by convolving the Q component of the ideal signal in the time domain and the impulse response of the filter characteristic of the Q-signal path. Furthermore, the predicted signal calculating section 34 may calculate, for a plurality of subsymbols, the I and Q components of the predicted signal represented in the time domain.

The EVM calculating section 36 calculates the root mean square of the errors (distances) that are measured on the I-Q plane between the ideal signal and the predicted signal for the plurality of resource blocks and provides the result as the EVM. The EVM calculating section 36 may alternatively output, as the EVM, the average among the root mean squares calculated for a plurality of subsymbols.

Having the above-described configuration, the error amount calculating section 30 can calculate the EVM without the need of actually supplying the device under measurement 200 with a SC-FDMA signal and measuring the resulting output signal. As a result, the measurement apparatus 10 can easily and swiftly calculate the EVM of the device under measurement 200 even when the device under measurement 200 is designed to modulate or demodulate an SC-FDMA signal.

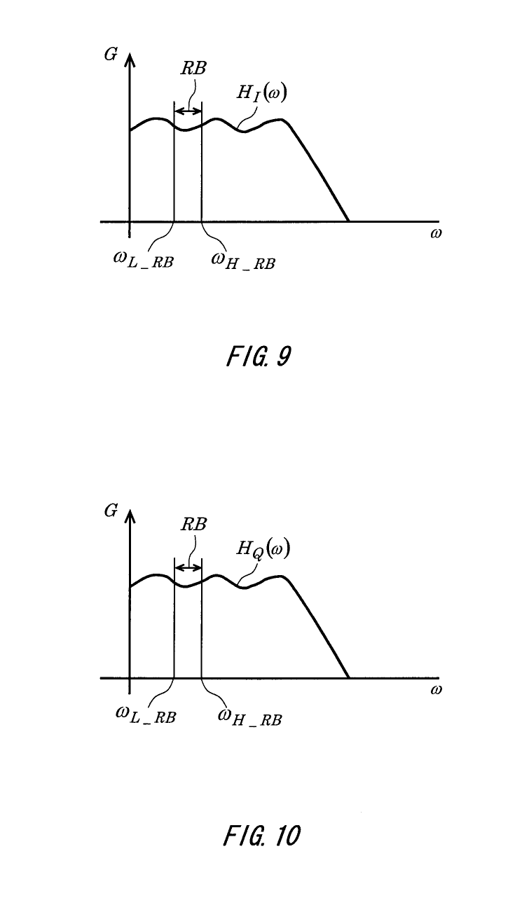

FIG. 9 illustrates, as an example, the filter characteristic (H_{I}(ω)) of the I-signal path of the device under measurement 200. FIG. 10 illustrates, as an example, the filter characteristic (H_{Q}(ω)) of the Q-signal path of the device under measurement 200.

According to the SC-FDMA-based communication standard, the transmission channel is divided into resource blocks in the frequency-time domain. According to the SC-FDMA-based communication standard, when a plurality of users share the transmission channel, each user is allocated with one or more resource blocks as its available transmission path.

Here, for each resource block, the time response converting section 38 performs inverse Fourier transform on the frequency characteristic H_{I}(ω) of the I-signal path of the device under measurement 200 using Expression 121 to calculate the impulse response h_{I}_{_{—}}_{RB}(t) of the filter characteristic of the I-signal path of the device under measurement 200.

$${h}_{I\_RB} ( t ) = {\int }_{{ω}_{L\_RB}}^{{ω}_{H\_RB}} {H}_{I} ( ω ) \cdot {e}^{j ω t} d ω \qquad ( 121 )$$

Here, t denotes the time, RB denotes the resource block number identifying one of the resource blocks that are included in the SC-FDMA signal, h_{I}_{_{—}}_{RB}(t) denotes the impulse response in the resource block RB of the filter characteristic of the I-signal path of the device under measurement 200, ω_{H}_{_{—}}_{RB} denotes the upper-limit of the angular frequencies of the resource block RB, and ω_{L}_{_{—}}_{RB} denotes the lower limit of the angular frequencies of the resource block RB. These definitions apply to Expressions 111 to 124.

Likewise, for each resource block, the time response converting section 38 performs inverse Fourier transform on the frequency characteristic H_{Q}(ω) of the Q-signal path of the device under measurement 200 using Expression 122 to calculate the impulse response h_{Q}_{_{—}}_{RB} (t) of the filter characteristic of the Q-signal path of the device under measurement 200.

$${h}_{Q\_RB} ( t ) = {\int }_{{ω}_{L\_RB}}^{{ω}_{H\_RB}} {H}_{Q} ( ω ) \cdot {e}^{j ω t} d ω \qquad ( 122 )$$

Here, h_{Q}_{_{—}}_{RB}(t) denotes the impulse response in the resource block RB of the filter characteristic of the Q-signal path of the device under measurement 200. This definition applies to Expressions 111 to 124.

The time response converting section 38 may calculate the impulse response for a collection of neighboring resource blocks. In this case, the ideal signal calculating section 32 generates the I and Q components of the ideal signal represented in the time domain, for each of a plurality of ranges corresponding to the frequency ranges for each of which the time response converting section 38 calculates the impulse response.

The predicted signal calculating section 34 calculates, for each resource block, the I and Q components of the predicted signal using Expression 123.

$$( \begin{matrix}{I}_{RB}^{′} ( t ) \\ {Q}_{RB}^{′} ( t )\end{matrix} ) = ( \begin{matrix}cos ( θ ) & sin ( θ ) \\ sin ( θ ) & cos ( θ )\end{matrix} ) ( \begin{matrix}{I}_{RB} ( t ) * {h}_{I\_RB} ( t ) \\ {Q}_{RB} ( t ) * {h}_{Q\_RB} ( t )\end{matrix} ) \qquad ( 123 )$$

In Expression 123, * denotes the convolution, I_{RB}(t) denotes the I component of the ideal signal, Q_{RB}(t) denotes the Q component of the ideal signal, I′_{RB}(t) denotes the I component of the predicted signal, and Q′_{RB}(t) denotes the Q component of the predicted signal. These definitions apply to Expressions 111 to 124.

Specifically speaking, the predicted signal calculating section 34 calculates, for each resource block, the I component I′_{RB}(t) of the predicted signal represented in the time domain by convolving the I component (I_{RB}(t)) of the ideal signal represented in the time domain and the impulse response (h_{I}_{_{—}}_{RB}(t) of the filter characteristic of the I-signal path. Also, the predicted signal calculating section 34 calculates, for each resource block, the Q component Q′_{RB}(t) of the predicted signal represented in the time domain by convolving the Q component (Q_{RB}(t)) of the ideal signal represented in the time domain and the impulse response (h_{Q}_{_{—}}_{RB} (t)) of the filter characteristic of the Q-signal path. Furthermore, the predicted signal calculating section 34 corrects the phases of the I and Q components of the predicted signal represented in the time domain using the carrier phase error θ of the device under measurement 200.

The EVM calculating section 36 calculates, for each resource block, the root mean square of the errors (distances) on the I-Q plane between the ideal signal and the predicted signal and provides the result as the EVM. In other words, the EVM calculating section 36 uses the following Expression 124 to calculate the EVM.

$$E V M = {C}_{2} \cdot \sqrt{{\sum }_{RB = 1}^{RBNUM} \frac{{( {I}_{RB}^{′} ( t ) - {I}_{RB} ( t ) )}^{2} + {( {Q}_{RB}^{′} ( t ) - {Q}_{RB} ( t ) )}^{2}}{{( {I}_{RB} ( t ) + {Q}_{RB} ( t ) )}^{2}}} \qquad ( 124 )$$

Here, RBNUM denotes the number of the resource blocks contained in the SC-FDMA signal, and C₂ denotes the constant determined according to the standard of the SC-FDMA signal. These definitions apply to Expressions 111 to 124.

As described above, the measurement apparatus 10 relating to the present embodiment can easily perform the EVM calculation when the device under measurement 200 is configured to modulate or demodulate SC-FDMA signals.

Having the configuration shown in FIG. 8, the error amount calculating section 30 can also perform the EVM calculation when the device under measurement 200 is configured to modulate or demodulate a quadrature amplitude modulation (QAM) signal. In this case, the error amount calculating section 30 may simply perform the same EVM calculation as the case where the device under measurement 200 is designed to modulate or demodulate an SC-FDMA signal, assuming that only one resource block is defined along the frequency axis.

In other words, the ideal signal calculating section 32 calculates the I and Q components of the ideal signal represented in the time domain for the frequency range of the QAM signal.

The time response converting section 38 calculates the impulse response of the filter characteristic of the I-signal path and the impulse response of the filter characteristic of the Q-signal path for the frequency range of the QAM signal. More specifically, the time response converting section 38 uses Expression 121 to calculate the impulse response of the filter characteristic of the I-signal path. The time response converting section 38 also uses Expression 122 to calculate the impulse response of the filter characteristic of the Q-signal path. When Expressions 121 and 122 are used, the upper-limit angular frequency of the frequency range of the QAM signal is substituted into the variable ω_{H}_{_{—}}_{RB} and the lower-limit angular frequency of the frequency range of the QAM signal is substituted into ω_{L}_{_{—}}_{RB}.

The predicted signal calculating section 34 calculates the I component of the predicted signal represented in the time domain by convolving the I component of the ideal signal in the time domain and the impulse response of the filter characteristic of the I-signal path, for the frequency range of the QAM signal. The predicted signal calculating section 34 also calculates the Q component of the predicted signal represented in the time domain by convolving the Q component of the ideal signal in the time domain and the impulse response of the filter characteristic of the Q-signal path, for the frequency range of the QAM signal.

The EVM calculating section 36 calculates the root mean square of the errors on the I-Q plane between the ideal signal and the predicted signal calculated in the above-described manner and provides the result as the EVM. In other words, the EVM calculating section 36 uses the following Expression 125 to calculate the EVM.

$$E V M = {C}_{3} \cdot \sqrt{\frac{{( {I}^{′} ( t ) - I ( t ) )}^{2} + {( {Q}^{′} ( t ) - Q ( t ) )}^{2}}{{( I ( t ) + Q ( t ) )}^{2}}} \qquad ( 125 )$$

Here, I(t) denotes the I component of the ideal signal, Q(t) denotes the Q component of the ideal signal, I′(t) denotes the I component of the predicted signal, Q′(t) denotes the Q component of the predicted signal, and C₃ denotes the constant determined according to the standard of the QAM signal.

As described above, the measurement apparatus 10 relating to the embodiment can easily perform the EVM calculation when the device under measurement 200 is designed to modulate or demodulate the QAM signal.

FIG. 11 illustrates the configuration of the I-Q error measuring section 20 relating to the embodiment, together with a quadrature modulator 300. The I-Q error measuring section 20 measures the frequency characteristic of the I-Q phase error, the frequency characteristic of the gain error, and the carrier phase error of the quadrature modulator 300, which is the device under measurement 200.

The I-Q error measuring section 20 includes a supplying section 112, a frequency shifting section 114, a bypass switch 116, a sampling section 118, an extracting section 120, a calculating section 122, an adjustment combining section 124, an I-side output switching section 126, an I-side output switching section 128, an input switching section 130, and an adjusting section 132.

The supplying section 112 supplies the quadrature modulator 300 with, at different timings, a reference I signal corresponding to the I component of an IQ signal, which is to be modulated into a tone signal, and a reference Q signal corresponding to the Q component of the IQ signal. Here, the supplying section 112 inputs the reference I signal into the input end of the I signal of the quadrature modulator 300 and inputs the reference Q signal to the input end of the Q signal of the quadrature modulator 300.

According to the present embodiment, the supplying section 112 supplies the quadrature modulator 300 with, at different timings, reference I and Q signals corresponding to an IQ signal that is to be modulated into a multitone signal containing tone signals at either positive frequencies or negative frequencies. Here, a multitone signal is a modulated signal that contains tone signals respectively at a plurality of frequencies (ω₁, ω₂, ω₃, . . . , (ωₖ). Here, k is any natural number. Alternatively, the supplying section 112 may supply the quadrature modulator 300 with reference I and Q signals corresponding to an IQ signal that is to be modulated into a monotone signal. Here, a monotone signal is a modulated signal that contains a tone signal only at a single frequency. Here, the positive frequencies refer to frequencies higher than the carrier frequency of the modulated signal, and the negative frequencies refer to frequencies lower than the carrier frequency of the modulated signal.

For example, the supplying section 112 includes a waveform generating section 142, an I-side DAC 144, and a Q-side DAC 146. The waveform generating section 142 generates the waveform data of the reference I signal and the waveform data of the reference Q signal at different timings.

For example, the waveform generating section 142 outputs, as the waveform data of the reference I signal, the data representing the waveform obtained by adding together sinusoidal waves (for example, cosine waves) individually having predetermined frequencies and phases. For example, the waveform generating section 142 outputs, as the waveform data of the reference Q signal, the data representing the waveform obtained by adding together sinusoidal waves (for example, sine waves) whose phases are shifted by 90 degrees with respect to the phases of the reference I signal.

The waveform generating section 142 supplies the waveform data of the reference I signal to the I-side DAC 144. The waveform generating section 142 also supplies the waveform data of the reference Q signal to the Q-side DAC 146.

The I-side DAC 144 digital-analog converts the waveform data of the reference I signal, supplied from the waveform generating section 142, and inputs the result into the I signal input end of the quadrature modulator 300. The Q-side DAC 146 digital-analog converts the waveform data of the reference Q signal, supplied from the waveform generating section 142, and inputs the result into the Q signal input end of the quadrature modulator 300.

In the above-described manner, the supplying section 112 can supply the quadrature modulator 300 with, at different timings, the reference I and Q signals. In response to the reception of the reference I signal, the quadrature modulator 300 modulates the received reference I signal into the I component of the carrier signal, modulates a Q signal with an amplitude of 0 into the Q component of the carrier signal, and outputs the resulting modulated signal. In response to the reception of the reference Q signal, the quadrature modulator 300 modulates an I signal with an amplitude of 0 into the I component of the carrier signal, modulates the received reference Q signal into the Q component of the carrier signal, and outputs the resulting modulated signal.

The frequency shifting section 114 down-converts the carrier frequency of the modulated signal output from the quadrature modulator 300 into an intermediate frequency and supplies the result to the sampling section 118. The bypass switch 116 allows the modulated signal output from the quadrature modulator 300 to bypass the frequency shifting section 114 and to be directly supplied to the sampling section 118, when it is not necessary to perform the down-conversion by the frequency shifting section 114.

The sampling section 118 samples and digitizes the modulated signal output from the frequency shifting section 114. The sampling section 118 samples and digitizes the modulated signal directly output from the quadrature modulator 300 when it is not necessary to perform the down-conversion by the frequency shifting section 114.

The extracting section 120 extracts the frequency component (may be referred to as an I-signal frequency component) corresponding to the tone signal contained in the modulated signal that is output from the quadrature modulator 300 in response to the input of the reference I signal. The extracting section 120 also extracts the frequency component (may be referred to as a Q-signal frequency component) corresponding to the tone signal contained in the modulated signal that is output from the quadrature modulator 300 in response to the input of the reference Q signal. For example, the extracting section 120 extracts the I- and Q-signal frequency components that are the frequency components corresponding to the tone signals, by performing discrete Fourier transform (for example, fast Fourier transform) on the modulated signal that has been digitized by the sampling section 118.

Here, the extracting section 120 extracts, as the frequency component corresponding to the tone signal, the signal component at the frequency of the tone signal and the signal component at the frequency that is symmetrically positioned to the frequency of the tone signal with respect to the carrier frequency (ω₀). For example, when the frequency of the tone signal is ωₖ and the carrier frequency is ω0, the extracting section 120 extracts the signal component at the frequency (ω₀+ωₖ) and the signal component at the frequency (ω₀−ωₖ).

The calculating section 122 calculates the frequency characteristic of the phase error of the quadrature modulator 300 and the frequency characteristic of the gain error of the quadrature modulator 300, based on the I- and Q-signal frequency components extracted by the extracting section 120. The calculating section 122 further calculates the carrier phase error of the quadrature modulator 300.

The above-described extracting section 120 and calculating section 122 are, for example, implemented by a processor. The calculations performed by the calculating section 122 will be described later in detail.

The adjustment combining section 124 combines an adjustment I signal and an adjustment Q signal output from the supplying section 112 and supplies the result to the sampling section 118 during an adjustment operation performed prior to the measurement of the I-Q error.

The I-side output switching section 126 and the Q-side output switching section 128 allow the signals output from the supplying section 112 to be supplied to different destinations between the I-Q error measurement operation and the adjustment operation. During the I-Q error measurement operation, the I-side output switching section 126 and the Q-side output switching section 128 allow the reference I and Q signals output from the supplying section 112 to be supplied to the quadrature modulator 300. During the adjustment operation, the I-side output switching section 126 and the Q-side output switching section 128 allow the adjustment I and Q signals output from the supplying section 112 to be supplied to the adjustment combining section 124.

The input switching section 130 allows different signals to be input into and sampled by the sampling section 118 between the I-Q error measurement operation and the adjustment operation. During the I-Q error measurement operation, the input switching section 130 allows the modulated signal output from the quadrature modulator 300 to be sampled by the sampling section 118. During the adjustment operation, the input switching section 130 allows the combined signal output from the adjustment combining section 124 to be sampled by the sampling section 118.

The adjusting section 132 adjusts the error (for example, the frequency error, the phase error, and the gain error) between the reference I signal and the reference Q signal output from the supplying section 112. For example, the adjusting section 132 causes the supplying section 112 to output the predetermined adjustment I and Q signals so that the adjustment I and Q signals are sampled by the sampling section 118. The adjusting section 132 adjusts the waveforms of the reference I and Q signals output from the supplying section 112 based on the results of the sampling. For example, the adjusting section 132 adjusts the error between the reference I signal and the reference Q signal output from the supplying section 112 using the methods disclosed in International Publications Nos. 2007/072653 and 2007/077686.

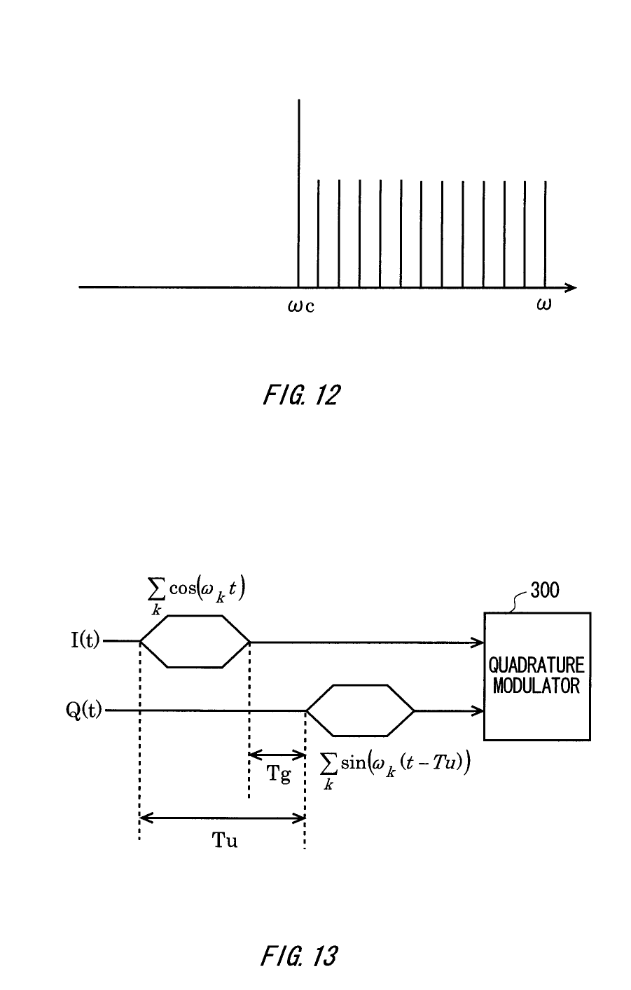

FIG. 12 illustrates, as an example, a multitone signal output from an ideal quadrature modulator in response to the reference I signal and the reference Q signal that are simultaneously supplied to the ideal quadrature modulator. FIG. 13 illustrates, as an example, when to supply the reference I signal and the reference Q signal to the quadrature modulator 300.

The supplying section 112 of the I-Q error measuring section 20 outputs a reference I signal and a reference Q signal that are to be modulated into generate the multitone signal illustrated in FIG. 12. Furthermore, the supplying section 112 supplies the quadrature modulator 300 with, at different timings, the reference I and Q signals in such a manner that the waveforms thereof do not overlap, as shown in FIG. 13.

For example, when supplying the quadrature modulator 300 with the reference I signal and the reference Q signal, the supplying section 112 delays one of the signals by a time (Tu) longer than the duration of the waveform of the reference I signal (same as the duration of the waveform of the reference Q signal). When there is a filter or the like as the following stage of the quadrature modulator 300, the waveform of the modulated signal output from the quadrature modulator 300 is widened due to distortion and the like. Thus, it is preferable for the supplying section 112 to provide a predetermined guard time (Tg) between the reference I signal and the reference Q signal.

Furthermore, the supplying section 112 preferably supplies the quadrature modulator 300 with the reference I signal and the reference Q signal successively without stopping the clock. In this way, the I-Q error measuring section 20 can accurately extract the frequency characteristics of the reference I signal and the reference Q signal without correcting the phase error of the sampling clock.

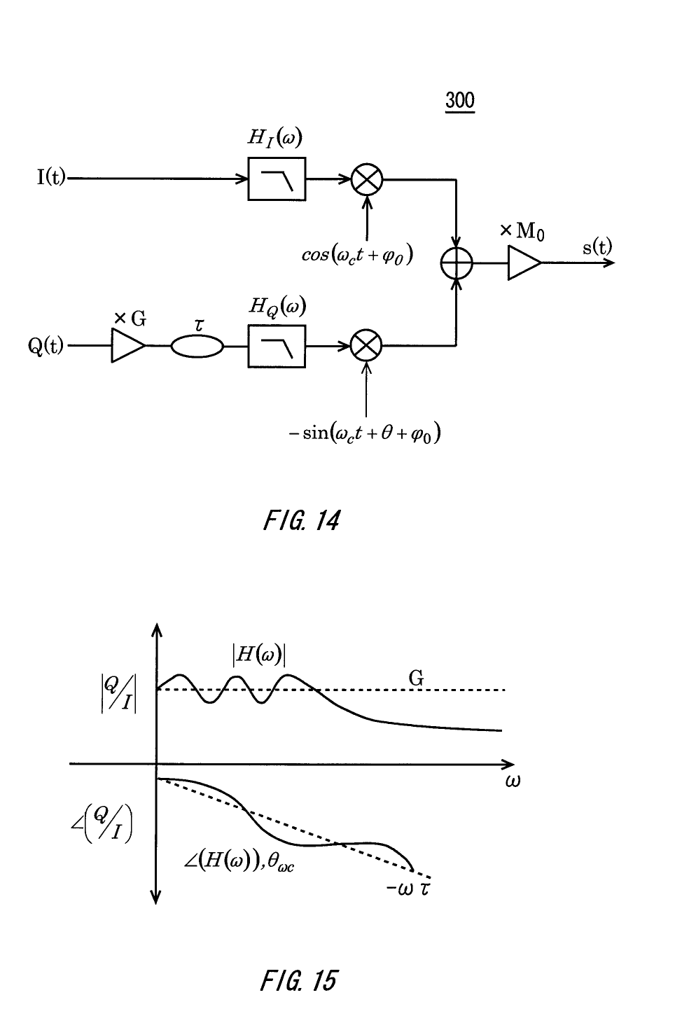

FIG. 14 illustrates the model of the error of the quadrature modulator 300. The following describes the model of the error of the quadrature modulator 300. The variables used in the description of model of the error are defined as follows.

Specifically speaking, t denotes the time, ωc denotes the carrier frequency, ω₀ denotes the angular frequency of the signal input into the quadrature modulator 300, I(t) denotes the temporal waveform of the I signal input into the quadrature modulator 300, Q(t) denotes the temporal waveform of the Q signal input into the quadrature modulator 300, s(t) denotes the temporal waveform of the modulated signal output from the quadrature modulator 300, H_{I}(ω) denotes the filter characteristic of the I-signal path of the quadrature modulator 300 as a function of the angular frequency ω, H_{Q}(ω) denotes the filter characteristic of the Q-signal path of the quadrature modulator 300 as a function of the angular frequency ω, M₀ denotes the gain of the quadrature modulator 300, G denotes the I-Q gain error of the quadrature modulator 300, τ denotes the I-Q skew of the quadrature modulator 300, θ and θωc denote the carrier phase error of the quadrature modulator 300, and φ denotes the initial phase of the carrier signal.

In the model of the error shown in FIG. 14, the modulated signal s(t) output from the quadrature modulator 300 is given by the following Expression 1 when the variables H_{I}(ω), H_{Q}(ω) and τ are ignored.

$$\begin{matrix}s ( t ) = {M}_{0} \cdot \{ I ( t ) \cdot cos ( {ω}_{c} t + {ϕ}_{0} ) - G \cdot Q ( t ) \cdot sin ( {ω}_{c} t + {ϕ}_{0} + θ ) \} \\ = {M}_{0} \cdot \{ \begin{matrix}( I ( t ) - Q ( t ) \cdot G \cdot sin ( θ ) ) \cdot cos ( {ω}_{c} t + {ϕ}_{0} ) - \\ Q ( t ) \cdot G \cdot cos ( θ ) \cdot sin ( {ω}_{c} t + {ϕ}_{0} )\end{matrix} \}\end{matrix} \qquad ( 1 )$$

When this modulated signal s(t) is demodulated by an ideal quadrature demodulator, a baseband signal R(t) resulting from the demodulation is given by the following Expression 2. Here, the I-Q gain error G and the carrier phase error θ are assumed to be included in the Q signal.

$$\begin{matrix}\overline{R} ( t ) = \frac{{M}_{0} \cdot {e}^{{jϕ}_{0}}}{2} \cdot \{ ( I ( t ) - Q ( t ) \cdot G \cdot sin ( θ ) ) + j \cdot Q ( t ) \cdot G \cdot cos ( θ ) \} \\ = \frac{{M}_{0} \cdot {e}^{{jϕ}_{0}}}{2} \cdot \{ I ( t ) + j \cdot Q ( t ) \cdot G \cdot ( cos ( θ ) + j \cdot sin ( θ ) ) \} \\ = \frac{{M}_{0} \cdot {e}^{{jφ}_{0}}}{2} \cdot \{ I ( t ) + j \cdot Q ( t ) \cdot G \cdot {e}^{jθ} \}\end{matrix} \qquad ( 2 )$$

Here, it is assumed that the quadrature modulator 300, which have an I-Q skew of τ, is supplied with a reference I signal and a reference Q signal with an angular frequency ω₀. The I-Q skew is assumed to be contained in the Q signal.

In this case, the baseband signal resulting from the demodulation by the ideal quadrature demodulator is calculated by assigning cos(ω₀t) to the variable I(t) of Expression 2 and assigning sin(ω₀(t−τ)) to the variable Q(t). In other words, the baseband signal is given by the following Expression 3.

$$\frac{{M}_{0} \cdot {e}^{{jφ}_{0}}}{2} \cdot \{ I ( t ) + j \cdot Q ( t ) \cdot G \cdot {e}^{jθ} \} = \frac{{M}_{0} \cdot {e}^{{jφ}_{0}}}{2} \cdot \{ \frac{{e}^{{jω}_{0} t} + {e}^{- {jω}_{0} t}}{2} + j \cdot \frac{{e}^{{jω}_{0} ( t - τ )} - {e}^{- {jω}_{0} ( t - τ )}}{2 j} \cdot G \cdot {e}^{jθ} \} = \frac{{M}_{0} \cdot {e}^{{jϕ}_{0}}}{2} \cdot \{ \frac{( 1 + G \cdot {e}^{jθ} \cdot {e}^{- {jω}_{0} τ} ) {e}^{{jω}_{0} t}}{2} + \frac{( 1 - G \cdot {e}^{jθ} \cdot {e}^{{jω}_{0} τ} ) {e}^{- {jω}_{0} t}}{2} \} = \frac{{M}_{0} \cdot {e}^{{jφ}_{0}}}{4} \cdot \{ ( 1 + G \cdot {e}^{jθ} \cdot {e}^{- {jω}_{0} τ} ) {e}^{{jω}_{0} t} + ( 1 - G \cdot {e}^{jθ} \cdot {e}^{{jω}_{0} τ} ) {e}^{- {jω}_{0} t} \} \qquad ( 3 )$$

Here, H_{I}(ω₀) denotes the filter characteristic of the I-signal path of the quadrature modulator 300 and H_{Q}(ω₀) denotes the filter characteristic of the Q-signal path of the quadrature modulator 300. The baseband signal resulting from the demodulation by the ideal quadrature demodulator is given by the following Expression 4.

$$\frac{{M}_{0} \cdot {e}^{{jφ}_{0}}}{2} \cdot \{ I ( t ) + j \cdot Q ( t ) \cdot G \cdot {e}^{jθ} \} = \frac{{M}_{0} \cdot {e}^{{jφ}_{0}}}{2} \cdot \{ \frac{{H}_{I} ( {ω}_{0} ) {e}^{{jω}_{0} t} + {H}_{I} ( - {ω}_{0} ) {e}^{- {jω}_{0} t}}{2} + j \cdot \frac{{H}_{Q} ( {ω}_{0} ) {e}^{{jω}_{0} ( t - τ )} - {H}_{Q} ( - {ω}_{0} ) {e}^{- {jω}_{0} ( t - τ )}}{2 j} \cdot G \cdot {e}^{jθ} \} = \frac{{M}_{0} \cdot {e}^{{jϕ}_{0}}}{4} \cdot \{ {H}_{I} ( {ω}_{0} ) ( 1 + \frac{{H}_{Q} ( {ω}_{0} )}{{H}_{I} ( {ω}_{0} )} G \cdot {e}^{jθ} \cdot {e}^{- {jω}_{0} τ} ) {e}^{{jω}_{0} t} + {H}_{I} ( - {ω}_{0} ) ( 1 - \frac{{H}_{Q} ( - {ω}_{0} )}{{H}_{I} ( - {ω}_{0} )} G \cdot {e}^{jθ} \cdot {e}^{{jω}_{0} τ} ) {e}^{- {jω}_{0} t} \} \qquad ( 4 )$$

Specifically speaking, Expression 4 represents the baseband signal resulting from the demodulation by the ideal quadrature demodulator, when the reference I and Q signals with the angular frequency ω₀ are supplied to the quadrature modulator 300, where G denotes the I-Q gain error of the quadrature modulator 300, τ denotes the I-Q skew of the quadrature modulator 300, θ denotes the carrier phase error of the quadrature modulator 300, H_{I}(ω₀) denotes the filter characteristic of the I-signal path of the quadrature modulator 300, and the H_{Q}(ω₀) denotes the filter characteristic of the Q-signal path of the quadrature modulator 300. Referring to Expression 4, the frequency characteristic of the baseband signal contained in the modulated signal s(t) output from the quadrature modulator 300 is given by the following Expression 5.

$$\{ \begin{matrix}A ( {ω}_{0} ) = \frac{{M}_{0} \cdot {e}^{{jϕ}_{0}}}{4} \cdot {H}_{I} ( {ω}_{0} ) ( 1 + H ( {ω}_{0} ) G \cdot {e}^{jθ ( ω )} \cdot {e}^{- {jω}_{0} τ} ) \\ B ( - {ω}_{0} ) = \frac{{M}_{0} \cdot {e}^{{jϕ}_{0}}}{4} \cdot {H}_{I} ( - {ω}_{0} ) ( 1 - H ( - {ω}_{0} ) G \cdot {e}^{jθ ( ω )} \cdot {e}^{{jω}_{0} τ} )\end{matrix} \qquad ( 5 )$$

In Expression 5, A(ω₀) denotes the signal component at the positive frequency of the baseband signal. In Expression 5, B(−ω₀) denotes the signal component at the negative frequency of the baseband signal. In Expression 5, H(ω₀) denotes the filter characteristic error between the I-signal path and the Q-signal path at the angular frequency ω₀ as represented by Expression 6.

$$H ( {ω}_{0} ) = \frac{{H}_{Q} ( {ω}_{0} )}{{H}_{I} ( {ω}_{0} )} \qquad ( 6 )$$

The following describes how to calculate the frequency characteristic of the phase error, the frequency characteristic of the gain error, and the carrier phase error of the quadrature modulator 300.

The following Expression 7 represents a baseband signal provided by an ideal quadrature demodulator by demodulating a modulated signal that is output from the quadrature modulator 300 in response to a reference I signal supplied thereto. The following Expression 8 represents a baseband signal provided by an ideal quadrature demodulator by demodulating a modulated signal that is output from the quadrature modulator 300 in response to a reference Q signal supplied thereto.

$$\begin{matrix}\tilde{I} ( t ) = \frac{{M}_{0} \cdot {e}^{{jϕ}_{0}}}{4} \cdot ( {H}_{I} ( ω ) {e}^{jω t} + {H}_{I} ( - ω ) {e}^{- jω t} ) & ( 7 ) \\ j \tilde{Q} ( t ) = \frac{{M}_{0} \cdot {e}^{{jϕ}_{0}}}{4} \cdot ( {H}_{Q} ( ω ) {e}^{jω ( t - τ )} - {H}_{Q} ( - ω ) {e}^{- jω ( t - τ )} ) G \cdot {e}^{{jθω}_{c}} & ( 8 )\end{matrix}$$

Referring to Expression 7, the I-signal frequency component corresponding to the tone signal contained in the modulated signal output from the quadrature modulator 300 in response to the reference I signal supplied thereto is given by the following Expression 9. Here, A_{I}(ω) denotes the positive frequency component of the I-signal frequency component, and B_{I}(−ω) denotes the negative frequency component of the I-signal frequency component.

$$\{ \begin{matrix}{A}_{I} ( ω ) = \frac{{M}_{0} \cdot {e}^{{jϕ}_{0}} {H}_{I} ( ω )}{4} \\ {B}_{I} ( - ω ) = \frac{{M}_{0} \cdot {e}^{{jϕ}_{0}} {H}_{I} ( - ω )}{4}\end{matrix} \qquad ( 9 )$$

Referring to Expression 7, the Q-signal frequency component corresponding to the tone signal contained in the modulated signal output from the quadrature modulator 300 in response to the reference Q signal supplied thereto is given by the following Expression 10. Here, A_{Q}(ω) denotes the positive frequency component of the Q-signal frequency component, and B_{Q}(−ω) denotes the negative frequency component of the Q-signal frequency component.

$$\{ \begin{matrix}j {A}_{Q} ( ω ) = \frac{{M}_{0} \cdot {e}^{{jϕ}_{0}}}{4} \cdot G \cdot {e}^{{jθω}_{c}} {H}_{Q} ( ω ) {e}^{- jωτ} \\ j {B}_{Q} ( - ω ) = \frac{{M}_{0} \cdot {e}^{{jϕ}_{0}}}{4} \cdot G \cdot {e}^{{jθω}_{c}} {H}_{Q} ( - ω ) {e}^{jωτ}\end{matrix} \qquad ( 10 )$$

The ratio P(ω) between the positive frequency component of the I-signal frequency component and the positive frequency component of the Q-signal frequency component is given by the following Expression 11.

$$\begin{matrix}P ( ω ) = \frac{j {A}_{Q} ( ω )}{{A}_{I} ( ω )} \\ = \frac{{H}_{Q} ( ω )}{{H}_{I} ( ω )} \cdot G \cdot {e}^{{jθω}_{c}} {e}^{- jωτ} \\ = \vert H ( ω ) \vert {e}^{- j ( ωτ - ∠ H ( ω ) )} \cdot G \cdot {e}^{{jθω}_{c}}\end{matrix} \qquad ( 11 )$$

The ratio N(−ω) between the negative frequency component of the I-signal frequency component and the negative frequency component of the Q-signal frequency component is given by the following Expression 12.

$$\begin{matrix}N ( - ω ) = \frac{j {B}_{Q} ( - ω )}{{B}_{I} ( - ω )} \\ = - \frac{{H}_{Q} ( - ω )}{{H}_{I} ( - ω )} \cdot G \cdot {e}^{{jθω}_{c}} {e}^{jωτ} \\ = - \vert H ( ω ) \vert {e}^{j ( ωτ - ∠ H ( ω ) )} \cdot G \cdot {e}^{{jθω}_{c}}\end{matrix} \qquad ( 12 )$$

Here, H(ω) is given by the following Expression 13.

$$H ( ω ) = \frac{{H}_{Q} ( ω )}{{H}_{I} ( ω )} \qquad ( 13 )$$

Referring to Expressions 11, 12 and 13, −N(−ω)/P(ω) is given by the following Expression 14.

$$\frac{- N ( - ω )}{P ( ω )} = {e}^{2 j ( ω τ - ∠ H ( ω ) )} \qquad ( 14 )$$

The result of halving the phase represented by Expression 14 is expressed by the following Expression 15.

$$\frac{1}{2} ( ∠ ( \frac{- N ( - ω )}{P ( ω )} ) ) = ωτ - ∠ H ( ω ) \qquad ( 15 )$$

In light of the above, the I-Q error measuring section 20 can calculate the phase error of the quadrature modulator 300 based on the value equal to half the phase represented as −N(−ω)/P(ω).

The value P(ω) given by Expression 11 is corrected by the phase error calculated using Expression 15, which yields the following Expression 16.

P′(ω)=P(ω)·e^{j(ωτ-∠H(ω))}=|H(ω)|·G·e^{jθω}^{_{c}} (16)

The amplitude (i.e., the absolute value of the vector) of the value expressed by Expression 16 is expressed as |H(ω)|·G. The phase of the value expressed by Expression 16 is θωc.

As described above, the I-Q error measuring section 20 can calculate the gain error of the quadrature modulator 300 by correcting P(ω) based on the phase error and then using the amplitude (i.e., the absolute value of the vector) of corrected P(ω). In addition, the I-Q error measuring section 20 can calculate the phase error of the quadrature modulator 300 by correcting P(ω) based on the phase error and then using the phase of corrected P(ω).

Referring to Expressions 11, 12 and 13, −N(−(ω)·P(ω) is also given by the following Expression 17.

$$- N ( - ω ) \cdot P ( ω ) = {\vert H ( ω ) \vert}^{2} \cdot {G}^{2} \cdot {e}^{j 2 {θ}_{{ω}_{c}}} \qquad ( 17 )$$

The square root of the amplitude (the absolute value of the vector) of the value expressed by Expression 17 is |H(ω)|·G. Half the phase of the value expressed by Expression 17 is θωc.

In light of the above, the I-Q error measuring section 20 can calculate the gain error of the quadrature modulator 300 based on the square root of the amplitude (i.e., the absolute value of the vector) of −N(−ω)/P(ω). The I-Q error measuring section 20 can also calculate the carrier phase error of the quadrature modulator 300 based on half the phase of −N(−ω)·P(ω).

The value P(ω) given by Expression 11 is corrected by the gain error and the carrier phase error calculated using Expression 17, which yields the following Expression 18.

P′(ω)=e^{-j(ωτ-∠H(ω))} (18)

The phase of the value expressed by Expression 18 is ωτ−∠H(ω). In light of the above, the I-Q error measuring section 20 can calculate the phase error of the quadrature modulator 300 by correcting P(ω) based on the gain error and the carrier phase error and then using the phase of corrected P(ω).

Here, the value P(ω) expressed by Expression 11 may be corrected only using the carrier phase error calculated using Expression 17. In this case, Expression 11 is converted into the following Expression 19.

P′(ω)=|H(ω)|·G·e^{-j(ωτ-∠H(ω))} (19)

The phase of the value expressed by Expression 19 is ωτ−∠H(ω). In light of the above, the I-Q error measuring section 20 can calculate the phase error of the quadrature modulator 300 by correcting P(ω) at least based on the carrier phase error and then using the phase of corrected P(ω).

Referring to Expressions 11, 12 and 13, −N(−ω)·P*(ω) is given by the following Expression 20. Here, P*(ω) denotes the complex conjugate of P(ω).

−N(−ω)·P*(ω)=|H(ω)|²·G²·e^{2j(ωτ-∠H(ω))} (20)

The square root of the amplitude (the absolute value of the vector) of the value expressed by Expression 20 is |H(ω)|·G. Half the phase of the value expressed by Expression 20 is ωτ−∠H(ω).

In light of the above, the I-Q error measuring section 20 can calculate the gain error of the quadrature modulator 300 based on the square root of the amplitude (i.e., the absolute value of the vector) of −N(−ω)·P*(ω). The I-Q error measuring section 20 can also calculate the phase error of the quadrature modulator 300 based on half the phase of −N(−ω)·P*(ω).

The value P(ω) given by Expression 11 is corrected by the gain error and the phase error calculated using Expression 20, which yields the following Expression 21.

$${P}^{′} ( ω ) = {e}^{j {θ}_{{ω}_{c}}} \qquad ( 21 )$$

The phase of the value expressed by Expression 21 is θωc. In light of the above, the I-Q error measuring section 20 can calculate the carrier phase error of the quadrature modulator 300 by correcting P(ω) based on the gain error and the phase error and then using the phase of corrected P(ω).

Here, the value P(ω) expressed by Expression 11 may be corrected only using the phase error calculated using Expression 20. In this case, Expression 11 is converted into the following Expression 22.

$${P}^{′} ( ω ) = \vert H ( ω ) \vert \cdot G \cdot {e}^{j {θ}_{{ω}_{c}}} \qquad ( 22 )$$

The phase of the value expressed by Expression 22 is θωc. In light of the above, the I-Q error measuring section 20 can calculate the carrier phase error of the quadrature modulator 300 by correcting P(ω) at least based on the phase error and then using the phase of corrected P(ω).

The I-Q error measuring section 20 may calculate the gain error and the phase error using Expression 20 and calculate the carrier phase error using Expression 17. The I-Q error measuring section 20 may calculate the gain error, the phase error, and the carrier phase error using any combination of the above-described equations.

FIG. 15 illustrates, as an example, the frequency characteristics of the I-Q error (the gain error (|Q/I|) and of the phase error (∠(Q/I)) of the quadrature modulator 300.

The frequency characteristic of the gain error (|Q/I|) is separated into a component (gain G) that is constant irrespective of the frequency and a component (ripple (|H(ω)|)) that can vary depending on the frequency, as shown in FIG. 15. Accordingly, to calculate the gain error, the I-Q error measuring section 20 preferably separates the gain error into the component (G) that is constant irrespective of the frequency and the ripple (|H(ω)|).

Here, the component (gain G) that is constant irrespective of the frequency is represented as the multiplying coefficient in the entire function representing the gain error. Accordingly, the I-Q error measuring section 20 can separate the constant component G and the ripple (|H(ω)|) by calculating the gain error for each angular frequency using the multitone signal and then estimating the function representing the gain error of the quadrature modulator 300.

The frequency characteristic of the phase error (∠(Q/I)) is separated into a skew (−ωτ) that linearly varies according to the frequency and a group delay (∠H(ω)) that nonlinearly varies according to the frequency, as shown in FIG. 15. Thus, to calculate the phase error, the I-Q error measuring section 20 preferably separates the phase error into the skew (τ) and the group delay (∠H(ω)).

Here, the skew (τ) is represented as the coefficient of the first-order term of the function representing the phase error of the quadrature modulator 300. Accordingly, the I-Q error measuring section 20 can separate the skew τ and the group delay (∠H(ω)) by calculating the phase error for each angular frequency using the multitone signal and estimating the function representing the phase error of the quadrature modulator 300.

When the equation representing H(ω) is estimated in advance, the I-Q error measuring section 20 can calculate the phase error, the gain error, and the carrier phase error in the following manner, instead of the above-described calculations.

The phase of P(ω) is expressed by the following Expression 23.

∠{P(ω)}=−(ωτ−∠H(ω))+θ_{ω}_{_{c}} (23)

In the case of ω=0, τ and H(ω) are 0. In other words, ω=0 means ωτ−|H(ω)|=0. Accordingly, the I-Q error measuring section 20 can calculate the carrier phase error θωc by calculating the phase of P(ω) for the DC frequency (w=0).

The I-Q error measuring section 20 uses the multitone signal to calculate the actually measured value of P(ω) for each angular frequency. Subsequently, the I-Q error measuring section 20 calculates the linear function representing P(ω) by fitting a linear equation having ω as its variable to the actually measured values of P(ω) calculated for a plurality of angular frequencies. For example, the I-Q error measuring section 20 uses the method of least squares to calculate the linear function that least differs from P(ω).

Referring to the thus calculated linear function, the gradient represents the skew τ, and the intercept corresponding to w=0 represents the carrier phase error. Accordingly, the I-Q error measuring section 20 can provide the gradient of the thus calculated linear function as the skew τ and the intercept corresponding to w=0 as the carrier phase error.

When the equation representing H(ω) is estimated in advance, the I-Q error measuring section 20 calculates the function representing P(ω) by fitting this equation to the actually measured values of P(ω) associated with a plurality of angular frequencies. For example, the I-Q error measuring section 20 uses the method of least squares to calculate the function that least differs from the actually measured values.

Referring to the thus calculated function, the coefficient of the first-order term represents the skew τ and the coefficient of the n-th-order term represents the group delay (H(ω)). Here, n is a number other than 1. Accordingly, the I-Q error measuring section 20 can provide the coefficient of the first-order term of the thus calculated function as the skew τ and the coefficient of the n-th order term as the group delay (H(ω)).

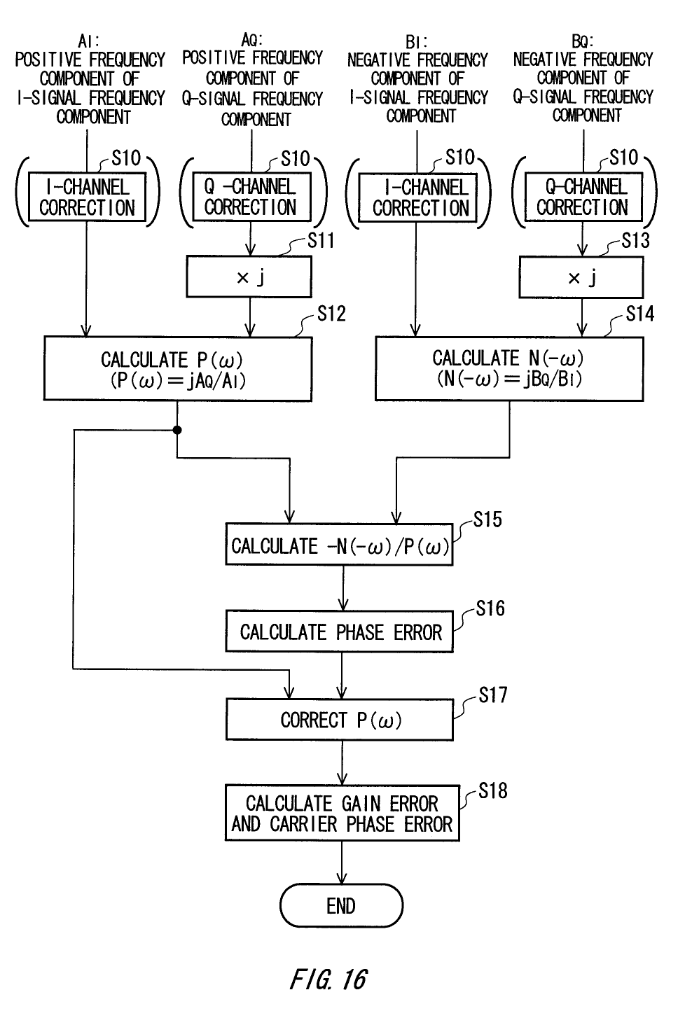

FIG. 16 is a flow chart illustrating an exemplary flow of operations performed by the calculating section 122 relating to the present embodiment. The calculating section 122 performs the operations illustrated in FIG. 16, for example, to calculate the phase error, the gain error, and the carrier phase error of the quadrature modulator 300.

Prior to the series of operations, the calculating section 122 receives, from the extracting section 120, the positive frequency component of the I-signal frequency component (A_{I}), the positive frequency component of the Q-signal frequency component (A_{Q}), the negative frequency component of the I-signal frequency component (B_{I}), and the negative frequency component of the Q-signal frequency component (B_{Q}).

Subsequently, the calculating section 122 performs channel correction on the received signal components (S10). Specifically speaking, the calculating section 122 performs channel correction on the positive frequency component of the I-signal frequency component (A_{I}) and the negative frequency component of the I-signal frequency component (B_{I}) using the correction coefficient designed to correct the channel of the I-signal path. The calculating section 122 also performs channel correction on the positive frequency component of the Q-signal frequency component (A_{Q}) and the negative frequency component of the Q-signal frequency component (B_{Q}) using the correction coefficient designed to correct the channel of the Q-signal path.

Following this, the calculating section 122 multiplies the positive frequency component of the Q-signal frequency component (A_{Q}) with an imaginary unit (j) (S11). The calculating section 122 then divides the result of multiplying the positive frequency component of the Q-signal frequency component (A_{Q}) with the imaginary unit (j) by the positive frequency component of the I-signal frequency component (jA_{Q}/A_{I}) to calculate P(ω) (S12).

Furthermore, the calculating section 122 multiplies the negative frequency component of the Q-signal frequency component (B_{Q}) with an imaginary unit (j) (S13). The calculating section 122 then divides the result of multiplying the negative frequency component of the Q-signal frequency component with the imaginary unit (j) (j×B_{Q}) by the negative frequency component of the I-signal frequency component (B_{I}) (jB_{Q}/B_{I}) to calculate N(−ω) (S12).

Following this, the calculating section 122 divides N(−ω) by P(ω) and reverses the +− sign of the result, thereby yielding −N(−ω)/P(ω) (S15). Subsequently, the calculating section 122 calculates the phase error for each of one or more angular frequencies ω at which one or more tone signals are generated (S16). Specifically speaking, the calculating section 122 provides half the phase of −N(−ω)/P(ω) as the phase error.

Subsequently, the calculating section 122 multiplies P(ω) calculated in the step S12 with the phase error calculated in the step S16 to correct P(ω) (S17). In this way, the calculating section 122 can remove, from P(ω), the influences of the phase error of the quadrature modulator 300.

Subsequently, the calculating section 122 calculates, for each of one or more angular frequencies ω at which one or more tone signals are generated, the gain error and the carrier phase error using corrected P(ω) (S18). Specifically speaking, the calculating section 122 provides the amplitude of corrected P(ω) as the gain error. The calculating section 122 provides the phase of corrected P(ω) as the carrier phase error.

As described above, the calculating section 122 can easily and accurately measure the phase error, the gain error, and the carrier phase error of the quadrature modulator 300. Furthermore, the calculating section 122 can calculate the frequency characteristic of the gain error and the frequency characteristic of the phase error by performing the above-described series of operations for the angular frequencies (ωₖ) of the tone signals contained in the multitone signal.

Furthermore, the calculating section 122 may separate the frequency characteristic of the gain error into the component that is constant irrespective of the frequency and the ripple that varies depending on the frequency. The calculating section 122 may also separate the frequency characteristic of the phase error into the skew that is represented by the first-order term and the group delay that is represented by an n-th-order term. Here, n is a number other than 1. In this way, the calculating section 122 can calculate the characteristics of the I-Q error of the quadrature modulator 300 in more detail.

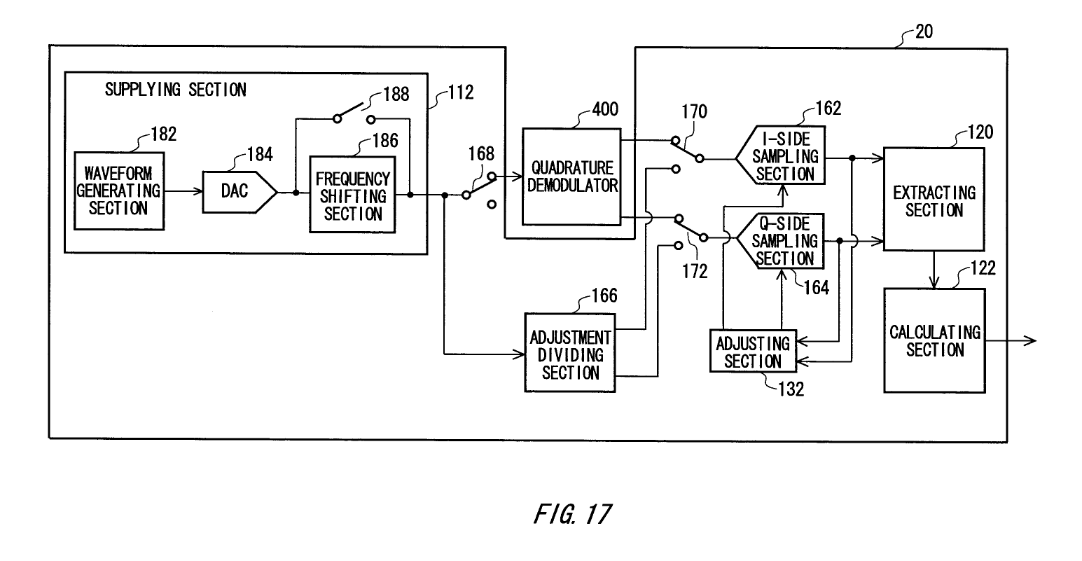

FIG. 17 illustrates the configuration of a modification example of the I-Q error measuring section 20, together with a quadrature demodulator 400. The modification example of the I-Q error measuring section 20 has substantially the same configuration and functions as the I-Q error measuring section 20 shown in FIG. 11. Thus, the constituents of the modification example having substantially the same functions as the corresponding constituents of the embodiment shown in FIG. 11 are designated by the same reference numerals and are not described in the following except for their differences.

According to the modification example, the I-Q error measuring section 20 measures the frequency characteristic of the I-Q phase error, the frequency characteristic of the I-Q gain error, and the I-Q carrier phase error of the quadrature demodulator 400, instead of the quadrature modulator 300. According to the modification example, the I-Q error measuring section 20 includes the supplying section 112, an I-side sampling section 162, a Q-side sampling section 164, the extracting section 120, the calculating section 122, an adjustment dividing section 166, an output switching section 168, an I-side input switching section 170, a Q-side input switching section 172, and the adjusting section 132.

The supplying section 112 supplies the quadrature demodulator 400 with, at different timings, a first modulated signal and a second modulated signal. The first modulated signal corresponds to the signal obtained by quadrature-modulating the I component of an IQ signal that is to be modulated into a tone signal, and the second modulated signal corresponds to the signal obtained by quadrature-modulating the Q component of the IQ signal. Specifically speaking, the supplying section 112 outputs, as the first modulated signal, a modulated signal generated by an ideal quadrature modulator by quadrature-modulating the reference I signal output from the supplying section 112 shown in FIG. 11. The supplying section 112 also outputs, as the second modulated signal, a modulated signal generated by an ideal quadrature modulator by quadrature-modulating the reference Q signal output from the supplying section 112 shown in FIG. 11.

The first modulated signal may correspond to the signal obtained by quadrature-modulating the I component of an IQ signal that is to be modulated into a multitone signal containing tone signals at either the positive frequencies or the negative frequencies, and the second modulated signal may correspond to the signal obtained by quadrature-modulating the Q component of the IQ signal. Alternatively, the first modulated signal may be obtained by quadrature-modulating the I component of an IQ signal that is to be modulated into a multitone signal in which mirror components do not overlap original components and the second modulated signal may be obtained by quadrature-modulating the Q component of the IQ signal.

For example, the supplying section 112 includes a waveform generating section 182, a DAC 184, a frequency shifting section 186, and a bypass switch 188. The waveform generating section 182 generates the waveform data of the first modulated signal and the waveform data of the second modulated signal at different timings. The DAC 184 digital-analog converts the waveform data supplied from the waveform generating section 182 into the first modulated signal and the second modulated signal.

The frequency shifting section 186 up-converts the carrier frequencies of the first and second modulated signals output from the supplying section 112 and supplies the result to the quadrature demodulator 400. The bypass switch 188 allows the first and second modulated signals output from the DAC 184 to bypass the frequency shifting section 186 and to be supplied to the quadrature demodulator 400, when it is not necessary to perform the up-conversion by the frequency shifting section 186.

In the above-described manner, the supplying section 112 can supply the quadrature demodulator 400 with, at different timings, the first and second modulated signals. The quadrature demodulator 400 can quadrature-demodulate the first modulated signal and resultantly output a baseband signal. The quadrature demodulator 400 can quadrature-demodulate the second modulated signal and resultantly output a baseband signal.

The I-side sampling section 162 samples and digitizes one of the baseband signals output from the quadrature demodulator 400 that corresponds to the I component. The Q-side sampling section 164 samples and digitizes one of the baseband signals output from the quadrature demodulator 400 that corresponds to the Q component.

The extracting section 120 extracts the frequency component corresponding to the tone signal included in the baseband signal obtained by the quadrature demodulator 400 by demodulating the first modulated signal. The extracting section 120 also extracts the frequency component corresponding to the tone signal included in the baseband signal obtained by the quadrature demodulator 400 by demodulating the second modulated signal.

The calculating section 122 calculates the frequency characteristic of the phase error, the frequency characteristic of the gain error, and the carrier phase error of the quadrature demodulator 400, based on the frequency component corresponding to the tone signal included in the baseband signal obtained by demodulating the first modulated signal and the frequency component corresponding to the tone signal included in the baseband signal obtained by demodulating the second modulated signal. The calculating section 122 may also calculate the carrier phase error of the quadrature demodulator 400.

The calculating section 122 treats the frequency component corresponding to the tone signal included in the baseband signal obtained by demodulating the first modulated signal, as the I-signal frequency component. The calculating section 122 also treats the frequency component corresponding to the tone signal included in the baseband signal obtained by demodulating the second modulated signal, as the Q-signal frequency component. The calculating section 122 calculates the phase error, the gain error, and the carrier phase error, in the same manner as the calculating section 122 shown in FIG. 11.

With the above-described configuration, the modification example of the I-Q error measuring section 20 can accurately and easily measure the phase error, the gain error, and the carrier phase error of the quadrature demodulator 400.

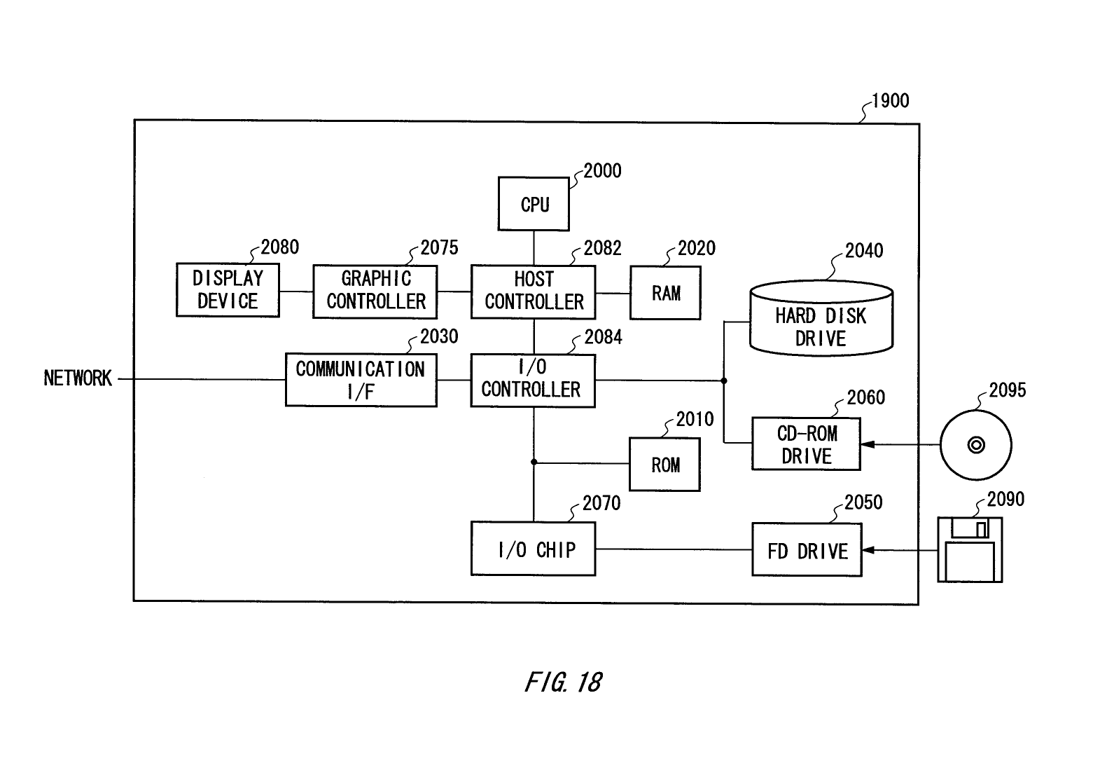

FIG. 18 illustrates an exemplary hardware configuration of a computer 1900 relating to an embodiment of the present invention. The computer 1900 relating to the present embodiment is constituted by a CPU surrounding section, an input/output (I/O) section and a legacy I/O section. The CPU surrounding section includes a CPU 2000, a RAM 2020, a graphic controller 2075 and a display device 2080 which are connected to each other by means of a host controller 2082. The I/O section includes a communication interface 2030, a hard disk drive 2040, and a CD-ROM drive 2060 which are connected to the host controller 2082 by means of an I/O controller 2084. The legacy I/O section includes a ROM 2010, a flexible disk drive 2050, and an I/O chip 2070 which are connected to the I/O controller 2084.

The host controller 2082 connects the RAM 2020 with the CPU 2000 and graphic controller 2075 which access the RAM 2020 at a high transfer rate. The CPU 2000 operates in accordance with programs stored on the ROM 2010 and RAM 2020, to control the constituents. The graphic controller 2075 obtains image data which is generated by the CPU 2000 or the like on a frame buffer provided within the RAM 2020, and causes the display device 2080 to display the obtained image data. Alternatively, the graphic controller 2075 may include therein a frame buffer for storing thereon the image data generated by the CPU 2000 or the like.

The I/O controller 2084 connects, to the host controller 2082, the hard disk drive 2040, communication interface 2030 and CD-ROM drive 2060 which are I/O devices operating at a relatively high rate. The communication interface 2030 communicates with different apparatuses via the network. The hard disk drive 2040 stores thereon programs and data to be used by the CPU 2000 in the computer 1900. The CD-ROM drive 2060 reads programs or data from a CD-ROM 2095, and supplies the read programs or data to the hard disk drive 2040 via the RAM 2020.

The I/O controller 2084 is also connected to the ROM 2010, flexible disk drive 2050 and I/O chip 2070 which are I/O devices operating at a relatively low rate. The ROM 2010 stores thereon a boot program executed by the computer 1900 at the startup and/or programs and the like dependent on the hardware of the computer 1900. The flexible disk drive 2050 reads programs or data from a flexible disk 2090, and supplies the read programs or data to the hard disk drive 2040 via the RAM 2020. The I/O chip 2070 is used to connect the flexible disk drive 2050 to the I/O controller 2084, and used to connect a variety of I/O devices to the I/O controller 2084, via a parallel port, a serial port, a keyboard port, a mouse port or the like.

The programs to be provided to the hard disk drive 2040 via the RAM 2020 are provided by a user in the state of being stored on a recording medium such as the flexible disk 2090, the CD-ROM 2095, and an IC card. The programs are read from the recording medium, and the read programs are installed in the hard disk drive 2040 in the computer 1900 via the RAM 2020, to be executed by the CPU 2000.

The programs that are installed in the computer 1900 and configure the computer 1900 to function as the error amount calculating section 30 to calculate the EVM of an OFDM signal include an ideal signal calculating module, a predicted signal calculating module, and an EVM calculating module. The programs that configure the computer 1900 to function as the error amount calculating section 30 to calculate the EVM of an SC-FDMA signal include an ideal signal calculating module, a predicted signal calculating module, an EVM calculating module, and a time response converting module. These programs or modules request the CPU 2000 and the like to cause the computer 1900 to function as the ideal signal calculating section 32, the predicted signal calculating section 34, the EVM calculating section 36, and the time response converting section 38.

When read by the computer 1900, the information processing described in these programs functions as the ideal signal calculating section 32, the predicted signal calculating section 34, the EVM calculating section 36 and the time response converting section 38, which are concrete means realized as a result of cooperation between the software and the above-described variety of hardware resources. The concrete means performs operations on or manipulates information according to the intended use of the computer 1900 relating to the present embodiment, thereby implementing the error amount calculating section 30 dedicated to the intended use.

For example, when the computer 1900 desired to communicate with an external apparatus or the like, the CPU 2000 executes the communication program loaded onto the RAM 2020 and instructs the communication interface 2030 to perform communication based on the processing described in the communication program. Under the control of the CPU 2000, the communication interface 2030 reads transmission data stored in a transmission buffer region or the like on a storage apparatus such as the RAM 2020, the hard disk drive 2040, the flexible disk 2090, or the CD-ROM 2095 and transmits the read transmission data to the network, or writes reception data received from the network onto a reception buffer region or the like on the storage apparatus. In this way, the communication interface 2030 may exchange the transmission data and the reception data with the storage apparatus using the direct memory access (DMA) scheme. Alternatively, the CPU 2000 may be in charge of exchanging transmission and reception data, and, specifically speaking, read data from a data source such as the storage apparatus or the communication interface 2030 and write data into a data destination such as the communication interface 2030 or the storage apparatus.

The CPU 2000 also instructs the RAM 2020 to read all or some necessary ones of the files or databases stored on an external storage apparatus such as the hard disk drive 2040, the CD-ROM drive 2060 (CD-ROM 2095), the flexible disk drive 2050 (the flexible disk 2090) using DMA transfer or the like and performs a variety of operations on the data stored on the RAM 2020. The CPU 2000 then writes the processed data back to the external storage apparatus using DMA transfer. In such a case, the RAM 2020 has a function of temporarily storing therein the content of the external storage apparatus. Thus, in the present embodiment, the RAM 2020 and the external storage apparatus are generally referred to as a memory, a storage section, or a storage apparatus. The variety of information such as programs, data, tables, or databases used in the present embodiment are stored on such a storage apparatus and can be subjected to information processing. Here, the CPU 2000 can also retain a portion of the data stored on the RAM 2020 in a cache memory and perform reading and writing on the data stored on the cache memory. In such an embodiment, the cache memory also functions as part of the RAM 2020. Thus, in the present embodiment, the cache memory is also interchangeable with the RAM 2020, the memory and/or the storage apparatus, unless otherwise stated.

The CPU 2000 performs a variety of operations instructed by the instruction sequences of the programs on the data read from the RAM 2020 and writes the resulting data back to the RAM 2020. Here, the operations include the various logic and arithmetic operations, information processing, conditional judgment, information retrieval and permutation described in the present embodiment. For example, to make conditional judgment, the CPU 2000 compares the variety of variables described in the present embodiment with other variables or constants and judges whether the former is larger, smaller, no less than, no greater than, equal to the latter. When certain conditions are satisfied (or not satisfied), the CPU 2000 branches to a different instruction sequence or invokes a subroutine.

The CPU 2000 can search through the information stored on the files or databases stored within the storage apparatus. For example, a case is assumed where the storage apparatus stores therein a plurality of entries in each of which a value of a first attribute is associated with a value of a second attribute. The CPU 2000 searches through the entries stored in the storage apparatus to identify an entry having a value of the first attribute satisfying a designated condition, and reads the value of the second attribute stored in the identified entry. In this way, the CPU 2000 can retrieve the value of the second attribute associated with the value of the first attribute that satisfies the designated condition.

The programs or modules described above may be stored on an external recording medium. Such a recording medium is, for example, an optical recording medium such as DVD and CD, a magnet-optical recording medium such as MO, a tape medium, a semiconductor memory such as an IC card and the like, in addition to the flexible disk 2090 and CD-ROM 2095. Alternatively, the recording medium may be a storage device such as a hard disk or RAM which is provided in a server system connected to a dedicated communication network or the Internet, and the programs may be provided to the computer 1900 via the network.

While the embodiment(s) of the present invention has (have) been described, the technical scope of the invention is not limited to the above described embodiment(s). It is apparent to persons skilled in the art that various alterations and improvements can be added to the above-described embodiment(s). It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

What is claimed is:

1. A measurement apparatus for measuring a characteristic of a device under measurement provided with a quadrature modulator or a quadrature demodulator, the measurement apparatus comprising:
an I-Q error measuring section that measures a frequency characteristic of an I-Q error of the device under measurement; and
an error amount calculating section that calculates, based on the frequency characteristic of the I-Q error, an error amount observed when the device under measurement is supplied with a predetermined signal.

2. The measurement apparatus as set forth in claim 1, wherein
the error amount calculating section calculates an EVM based on an error between (i) an ideal signal that is expected to be output from an I-Q-error-free model of the device under measurement in response to the predetermined signal input thereto and (ii) a predicted signal that is expected to be output from an I-Q-error-inclusive model of the device under measurement that includes the I-Q error measured by the I-Q error measuring section in response to the predetermined signal input thereto.

3. The measurement apparatus as set forth in claim 2, wherein
the device under measurement is designed to modulate or demodulate an OFDM signal, and
the error amount calculating section includes:
an ideal signal calculating section that calculates the ideal signal;
a predicted signal calculating section that calculates the predicted signal; and
an EVM calculating section that outputs, as the EVM, a root mean square of errors, on an I-Q plane, between the ideal signal and the predicted signal, the errors being calculated for a plurality of frequencies.

4. The measurement apparatus as set forth in claim 3, wherein
the EVM calculating section outputs, as the EVM, an average of root mean squares calculated for a plurality of symbols of the OFDM signal.

5. The measurement apparatus as set forth in claim 4, wherein
the predicted signal calculating section calculates, for each of a plurality of frequencies, the predicted signal corresponding to a signal that is obtained by adding together (i) a component obtained by multiplying together a signal component at the frequency of the predetermined signal and a component at the frequency of the frequency characteristic of the I-Q error and (ii) a component obtained by multiplying together a signal component at a mirror frequency of the frequency of the predetermined signal and a complex conjugate of a component at the frequency of the frequency characteristic of the I-Q error.

6. The measurement apparatus as set forth in claim 5, wherein
the error amount calculating section calculates the EVM using the following Expression 101,
$$E V M = {C}_{1} \cdot \sqrt{\frac{{\sum }_{k = 1}^{ToneNum} {\vert \{ \begin{matrix}{G}_{A} ( {ω}_{k} ) ( - {H}_{I} ( {ω}_{k} ) + {H}_{Q} ( {ω}_{k} ) \cdot {e}^{jθ} ) + \\ {G}_{B} ( - {ω}_{k} ) ( {H}_{I}^{*} ( {ω}_{k} ) - {H}_{Q}^{*} ( {ω}_{k} ) \cdot {e}^{jθ} )\end{matrix} \} \vert}^{2}}{ToneNum}} , \qquad ( 101 )$$
where ToneNum denotes the number of subcarriers contained in the OFDM signal, k denotes a subcarrier number to identify one of the subcarriers contained in the OFDM signal, ωₖ denotes an angular frequency of a subcarrier k, G_{A}(ωₖ) denotes a signal component at the subcarrier k of the predetermined signal input into the models of the device under measurement, G_{B}(−ωₖ) denotes a signal component at a mirror subcarrier −k of the subcarrier k of the predetermined signal input into the models of the device under measurement, H_{I}(ωₖ) denotes a component at the angular frequency ωₖ of a filter characteristic of an I-signal path and H_{Q}(ωₖ) denotes a component at the angular frequency ωₖ of a filter characteristic of a Q-signal path where the frequency characteristic of the I-Q error is separated into the filter characteristic of the I-signal path and the filter characteristic of the Q-signal path, H_{I}*(ωₖ) denotes a complex conjugate of the component at the angular frequency ωₖ of the filter characteristic of the I-signal path, H_{Q}*(ωₖ) denotes a complex conjugate of the component at the angular frequency ωₖ of the filter characteristic of the Q-signal path, θ denotes an I-Q carrier phase error of the device under measurement, and C₁ denotes a constant determined according to a standard of the OFDM signal.

7. The measurement apparatus as set forth in claim 3, wherein
the EVM calculating section calculates the EVM by multiplying the signal component at a subcarrier k with a component at the subcarrier k of a correction characteristic for correcting a channel characteristic by transmitting a modulated signal containing a pilot signal of a predetermined signal point and by multiplying the signal component at a mirror subcarrier −k with a component at the mirror subcarrier −k of the correction characteristic.

8. The measurement apparatus as set forth in claim 2, wherein
the device under measurement is designed to modulate or demodulate an SC-FDMA signal, and
the error amount calculating section includes:
an ideal signal calculating section that calculates an I component and a Q component of the ideal signal represented in a time domain, for each of a plurality of resource blocks that are frequency multiplexing ranges defined in the SC-FDMA signal;
a time response converting section that calculates, for each of the resource blocks, an impulse response of a filter characteristic of an I-signal path and an impulse response of a filter characteristic of a Q-signal path, where the frequency characteristic of the I-Q error is separated into the filter characteristic of the I-signal path and the filter characteristic of the Q-signal path;
a predicted signal calculating section that calculates, for each of the resource blocks, an I component of the predicted signal, represented in the time domain, by convolving the I component of the ideal signal in the time domain and the impulse response of the filter characteristic of the I-signal path and that calculates, for each of the resource blocks, a Q component of the predicted signal, represented in the time domain, that is obtained by convolving the Q component of the ideal signal in the time domain and the impulse response of the filter characteristic of the Q-signal path; and
an EVM calculating section that calculates a root mean square of errors that are calculated for the resource blocks, on an I-Q plane, between the ideal signal and the predicted signal and provides the root mean square as the EVM.

9. The measurement apparatus as set forth in claim 8, wherein
the EVM calculating section calculates the EVM using the following Expression 102,
$$E V M = {C}_{2} \cdot \sqrt{\frac{{\sum }_{RB = 1}^{RBNUM} {( {I}_{RB}^{′} ( t ) - {I}_{RB} ( t ) )}^{2} + {( {Q}_{RB}^{′} ( t ) - {Q}_{RB} ( t ) )}^{2}}{{( {I}_{RB} ( t ) + {Q}_{RB} ( t ) )}^{2}}} , \qquad ( 102 )$$
where t denotes a time, RBNUM denotes the number of resource blocks included in the SC-FDMA signal, RB denotes a resource block number for identifying one of the resource blocks included in the SC-FDMA signal, I_{RB}(t) denotes the I component of the ideal signal, Q_{RB}(t) denotes the Q component of the ideal signal, I′_{RB}(t) denotes the I component of the predicted signal, Q′_{RB}(t) denotes the Q component of the predicted signal, and C₂ denotes a constant determined according to a standard of the SC-FDMA signal.

10. The measurement apparatus as set forth in claim 2, wherein
the device under measurement is designed to modulate or demodulate a quadrature amplitude modulation signal, and
the error amount calculating section includes:
an ideal signal calculating section that calculates, for a frequency range of the quadrature amplitude modulation signal, an I component and a Q component of the ideal signal represented in a time domain;
a time response converting section that calculates, for the frequency range of the quadrature amplitude modulation signal, an impulse response of a filter characteristic of an I-signal path and an impulse response of a filter characteristic of a Q-signal path, where the frequency characteristic of the I-Q error is separated into the filter characteristic of the I-signal path and the filter characteristic of the Q-signal path;
a predicted signal calculating section that calculates, for the frequency range of the quadrature amplitude modulation signal, (i) an I component of the predicted signal represented in the time domain by convolving the I component of the ideal signal in the time domain and the impulse response of the filter characteristic of the I-signal path and (ii) a Q component of the predicted signal represented in the time domain by convolving the Q component of the ideal signal in the time domain and the impulse response of the filter characteristic of the Q-signal path; and
an EVM calculating section that calculates a root mean square of errors on an I-Q plane between the ideal signal and the predicted signal and provides the root mean square as the EVM.

11. The measurement apparatus as set forth in claim 10, wherein
the EVM calculating section calculates the EVM using the following Expression 103,
$$E V M = {C}_{3} \cdot \sqrt{\frac{{( {I}^{′} ( t ) - I ( t ) )}^{2} + {( {Q}^{′} ( t ) - Q ( t ) )}^{2}}{{( I ( t ) + Q ( t ) )}^{2}}} , \qquad ( 103 )$$
where t denotes a time, I_{RB}(t) denotes the I component of the ideal signal, Q_{RB}(t) denotes the Q component of the ideal signal, I′_{RB}(t) denotes the I component of the predicted signal, Q′_{RB}(t) denotes the Q component of the predicted signal, and C₃ denotes a constant determined according to a standard of the quadrature amplitude modulation signal.

12. The measurement apparatus as set forth in claim 2, wherein
the error amount calculating section calculates the EVM based on the error between the ideal signal and the predicted signal that are expected to be output from the models of the device under measurement in response to a signal of a signal point having a highest signal strength input thereto.

13. The measurement apparatus as set forth in claim 1, wherein
the device under measurement is a quadrature modulator, and
the I-Q error measuring section includes:
a supplying section that supplies the quadrature modulator with, at different timings, a reference I signal and a reference Q signal respectively corresponding to an I component and a Q component of an IQ signal that is modulated into a tone signal; and
a calculating section that calculates the frequency characteristic of the I-Q error based on an I-signal frequency component corresponding to a tone signal included in a modulated signal that is output from the quadrature modulator in response to the reference I signal supplied thereto and a Q-signal frequency component corresponding to a tone signal included in a modulated signal that is output from the quadrature modulator in response to the reference Q signal supplied thereto.

14. The measurement apparatus as set forth in claim 13, wherein
the calculating section calculates the frequency characteristic of the I-Q error based on the I-signal frequency components and the Q-signal frequency components corresponding to a plurality of tone signals at a plurality of frequencies.

15. The measurement apparatus as set forth in claim 14, wherein
the supplying section supplies the quadrature modulator with, at different timings, a reference I signal and a reference Q signal corresponding to an IQ signal that is to be modulated into a multitone signal containing tone signals at either positive frequencies or negative frequencies.

16. The measurement apparatus as set forth in claim 1, wherein
the device under measurement is a quadrature demodulator, and
the I-Q error measuring section includes:
a supplying section that supplies the quadrature demodulator with, at different timings, a first modulated signal corresponding to a signal obtained by quadrature modulating an I component of an IQ signal that is to be modulated into a tone signal and a second modulated signal corresponding to a signal obtained by quadrature modulating a Q component of the IQ signal; and
a calculating section that calculates the frequency characteristic of the I-Q error based on a baseband signal generated by the quadrature demodulator by demodulating the first modulated signal and a baseband signal generated by the quadrature demodulator by demodulating the second modulated signal.

17. The measurement apparatus as set forth in claim 16, wherein
the supplying section supplies the quadrature demodulator with, at different timings, a first modulated signal obtained by quadrature modulating an I component of an IQ signal that is modulated into a multitone signal containing tone signals at either positive frequencies or negative frequencies and a second modulated signal obtained by quadrature modulating a Q component of the IQ signal.

18. The measurement apparatus as set forth in claim 17, wherein
the supplying section supplies the quadrature demodulator with, at different timings, a first modulated signal that is obtained by quadrature modulating an I component of an IQ signal that is modulated into a multitone signal in which mirror components do not overlap original components and a second modulated signal that is obtained by quadrature modulating a Q component of the IQ signal.

19. A recording medium storing thereon a program to cause a computer to function as the error amount calculating section of the measurement apparatus as set forth in claim 1.

20. A measurement method for measuring a characteristic of a device under measurement provided with a quadrature modulator or a quadrature demodulator, the measurement method comprising:
measuring a frequency characteristic of an I-Q error of the device under measurement; and
calculating, based on the frequency characteristic of the I-Q error, an error amount observed when the device under measurement is supplied with a predetermined signal.
